(19) United States
(12) Patent Application Publication
(10) Pub. No.: US 2026/0007033 A1
(43) Pub. Date: Jan. 1, 2026

(54) DISPLAY DEVICE AND ELECTRONIC DEVICE

(71) Applicant: Samsung Display Co., LTD., Yongin-si (KR)

(72) Inventors: Jin Hyeong LEE, Yongin-si (KR); Israel Esteban LAZO MARTINEZ, Yongin-si (KR); Kyeong Jong KIM, Yongin-si (KR); Su Jeong KIM, Yongin-si (KR); Woo Young KIM, Yongin-si (KR); Jung Woo LEE, Yongin-si (KR)

(21) Appl. No.: 19/068,160

(22) Filed: Mar. 3, 2025

(30) Foreign Application Priority Data
Jul. 1, 2024 (KR) 10-2024-0086228

(51) Int. Cl. H10K 59/40; H10K 59/126; H10K 59/80; H10K 59/88; H10K 102/00

(52) U.S. Cl. CPC H10K 59/40; H10K 59/126; H10K 59/873; H10K 59/879; H10K 59/88; H10K 2102/3026

(57) ABSTRACT

A display device includes: a substrate, a light emitting element layer disposed on the substrate and including a bank and a light emitting element overlapping an opening of the bank in a plan view, a first touch conductive layer disposed on the light emitting element layer and including a first pattern electrode, a first insulating layer disposed on the first touch conductive layer, a second touch conductive layer disposed on the first insulating layer and including a second pattern electrode, a second insulating layer disposed on the second touch conductive layer, and a light blocking layer disposed on the second insulating layer and including a light blocking pattern, wherein at least a portion of the first pattern electrode, at least a portion of the second pattern electrode, and at least a portion of the light blocking pattern overlap the light emitting element in the plan view.

This application claims priority to Korean Patent Application No. 10-2024-0086228, filed on Jul. 1, 2024, and all the benefits accruing therefrom under 35 U.S.C. § 119, the content of which in its entirety is herein incorporated by reference.

### BACKGROUND

### 1. Field

The present disclosure relates to a display device and an electronic device.

### 2. Description of the Related Art

As the information society develops, demands for display devices for displaying images are increasing in various forms. The display devices may be displays such as liquid crystal displays, field emission displays, and light emitting displays. The light emitting displays may include an organic light emitting display including an organic light emitting diode element as a light emitting element and an inorganic light emitting display including an inorganic light emitting diode element as a light emitting element.

In the case of vehicle displays, if an image displayed on a vehicle display in front of a driver or a passenger is reflected in the windshield at night, it may interfere with the driver's driving. Therefore, it is desirable to control the viewing angle of the image displayed on the vehicle display. In addition, in order to protect privacy, it is desirable to control the viewing angle of an image displayed on the vehicle display in front of the driver so that the image displayed on the vehicle display is not provided to the passenger.

### SUMMARY

Aspects of the present disclosure provide a display device and an electronic device with improved viewing angle control characteristics.

Aspects of the present disclosure also provide a display device and an electronic device with improved process efficiency.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, there is provided a display device including: a substrate, a light emitting element layer disposed on the substrate and including a bank and a light emitting element overlapping an opening of the bank in a plan view, a first touch conductive layer disposed on the light emitting element layer and including a first pattern electrode, a first insulating layer disposed on the first touch conductive layer, a second touch conductive layer disposed on the first insulating layer and including a second pattern electrode, a second insulating layer disposed on the second touch conductive layer, and a light blocking layer disposed on the second insulating layer and including a light blocking pattern, where at least a portion of the first pattern electrode, at least a portion of the second pattern electrode, and at least a portion of the light blocking pattern overlap the light emitting element in the plan view.

In an embodiment, the first pattern electrode may include a first sub-pattern electrode and a second sub-pattern electrode disposed between the first sub-pattern electrode and another first sub-pattern electrode, the second pattern electrode may include a third sub-pattern electrode and a fourth sub-pattern electrode disposed between the third sub-pattern electrode and another third sub-pattern electrode, the first sub-pattern electrode, the another first sub-pattern electrode, the third sub-pattern electrode, and the another third sub-pattern electrode may overlap the bank in the plan view, and the second sub-pattern electrode and the fourth sub-pattern electrode may overlap the light emitting element in the plan view.

In an embodiment, the display device may further include a touch driver electrically connected to the first touch conductive layer and the second touch conductive layer, where the first through fourth sub-pattern electrodes may be electrically connected to the touch driver.

In an embodiment, widths of the first through fourth sub-pattern electrodes may be equal to each other.

In an embodiment, the first sub-pattern electrode and the third sub-pattern electrode may be connected through a touch contact hole.

In an embodiment, the display device may further include a color filter disposed on the light blocking layer, where the light blocking pattern may include a first light blocking pattern overlapping the first sub-pattern electrode and a second light blocking pattern overlapping the second sub-pattern electrode in the plan view, and the color filter may cover a portion of the first light blocking pattern and covers an entirety of the second light blocking pattern.

In an embodiment, a width of the light blocking pattern may be different from each of a width of the first pattern electrode and a width of the second pattern electrode.

In an embodiment, he display device may further include an encapsulation layer disposed between the light emitting element layer and the first touch conductive layer, where a refractive index of the first insulating layer may be greater than a refractive index of the encapsulation layer.

In an embodiment, the first pattern electrode may include a first sub-pattern electrode and a first dummy electrode disposed between the first sub-pattern electrode and another first sub-pattern electrode, the second pattern electrode may include a third sub-pattern electrode and a second dummy electrode disposed between the third sub-pattern electrode and another third sub-pattern electrode, the first sub-pattern electrode, the another first sub-pattern electrode, the third sub-pattern electrode and the another third sub-pattern electrode may overlap the bank in the plan view, and the first dummy electrode and the second dummy electrode may overlap the light emitting element in the plan view.

In an embodiment, the display device may further include a touch driver electrically connected to the first touch conductive layer and the second touch conductive layer, where the first sub-pattern electrode and the third sub-pattern electrode may be electrically connected to the touch driver, and the first dummy electrode and the second dummy electrode may be electrically insulated from the touch driver.

In an embodiment, a width of the first dummy electrode may be different from a width of the first sub-pattern electrode, and a width of the second dummy electrode may be different from a width of the third sub-pattern electrode.

In an embodiment, the first insulating layer may include a first lens portion and a second lens portion disposed alternately with the first lens portion, and each of the first lens portion and the second lens portion may include a surface convex toward the light blocking layer.

In an embodiment, a valley may be disposed between the first lens portion and the second lens portion, a portion of the first pattern electrode may be disposed under the valley, and a portion of the second pattern electrode may be disposed in the valley.

In an embodiment, the first lens portion and the second lens portion may be spaced apart from each other, and the portion of the first pattern electrode disposed under the valley and the portion of the second pattern electrode disposed in the valley directly may contact each other.

In an embodiment, the first lens portion and the second lens portion may directly contact each other or be integrally formed with each other, and the portion of the first pattern electrode disposed under the valley and the portion of the second pattern electrode disposed in the valley may be spaced apart from each other.

In an embodiment, the first pattern electrode may be provided in plurality, the first insulating layer may define an opening provided between the plurality of first pattern electrodes, and the second insulating layer may further be disposed in the opening of the first insulating layer.

In an embodiment, the display device may further include an encapsulation layer disposed between the light emitting element layer and the first touch conductive layer, where a refractive index of the second insulating layer may be greater than a refractive index of the encapsulation layer.

In an embodiment, the at least a portion of the second pattern electrode overlapping the light emitting element may include a first portion disposed on an upper surface of the first insulating layer and a second portion disposed on a side surface of the opening of the first insulating layer.

In an embodiment, the second portion may directly contact the at least a portion of the first pattern electrode overlapping the light emitting element in the plan view.

In an embodiment, the display device may further include a light transmitting layer disposed on the light blocking layer.

According to an aspect of the present disclosure, there is provided an electronic device including a display device. The display device includes: a substrate, a light emitting element layer disposed on the substrate and including a bank and a light emitting element overlapping an opening of the bank in a plan view, a first touch conductive layer disposed on the light emitting element layer and including a first pattern electrode, a first insulating layer disposed on the first touch conductive layer, a second touch conductive layer disposed on the first insulating layer and including a second pattern electrode, a second insulating layer disposed on the second touch conductive layer, and a light blocking layer disposed on the second insulating layer and including a light blocking pattern, where at least a portion of the first pattern electrode, at least a portion of the second pattern electrode, and at least a portion of the light blocking pattern overlap the light emitting element in the plan view.

According to a display device and an electronic device according to an embodiment of the present disclosure, viewing angle control characteristics can be effectively improved.

According to a display device and an electronic device according to an embodiment of the present disclosure, process efficiency can be effectively improved.

However, the effects of the present disclosure are not restricted to the one set forth herein. The above and other effects of the present disclosure will become more apparent to one of daily skill in the art to which the present disclosure pertains by referencing the claims.

### BRIEF DESCRIPTION OF THE DRAWINGS

These and/or other aspects will become apparent and more readily appreciated from the following description of the embodiments, taken in conjunction with the accompanying drawings in which:

FIG. 1 is a perspective view of a display device according to an embodiment;

FIG. 2 is a plan view of the display device according to the embodiment;

FIG. 3 is a schematic cross-sectional view of the display device taken along line X1-X1′ of FIG. 2;

FIG. 4 is a diagram of a case where the display device according to the embodiment is applied to a vehicle;

FIG. 5 is a plan view of a part of a display area according to an embodiment;

FIG. 6 is a cross-sectional view taken along line X2-X2′ of FIG. 5;

FIG. 7 is an enlarged view of area A of FIG. 6;

FIG. 8 is an enlarged view of area A of FIG. 6 in a display device according to another embodiment;

FIG. 9 is an enlarged view of area A of FIG. 6 in a display device according to still another embodiment;

FIG. 10 is a cross-sectional view of a display device according to another embodiment;

FIG. 11 is an enlarged view of area B of FIG. 10;

FIG. 12 is an enlarged view of area B of FIG. 10 in a display device according to another embodiment;

FIG. 13 is a cross-sectional view of a display device according to still another embodiment;

FIG. 14 is an enlarged view of area C of FIG. 13;

FIG. 15 is an enlarged view of area C of FIG. 13 in a display device according to another embodiment;

FIG. 16 is a cross-sectional view of a display device according to yet another embodiment; and

FIG. 17 is an enlarged view of area D of FIG. 16.

### DETAILED DESCRIPTION

The invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will filly convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Hereinafter, embodiments of the present disclosure will be described in detail with reference to the accompanying drawings.

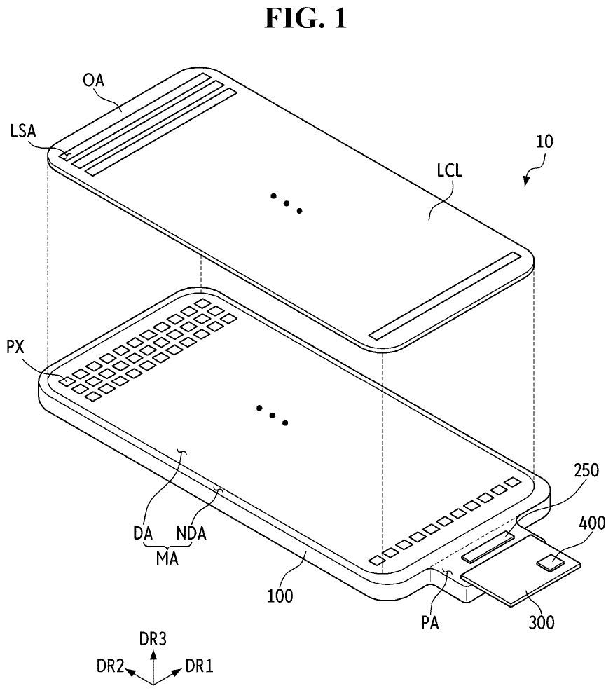

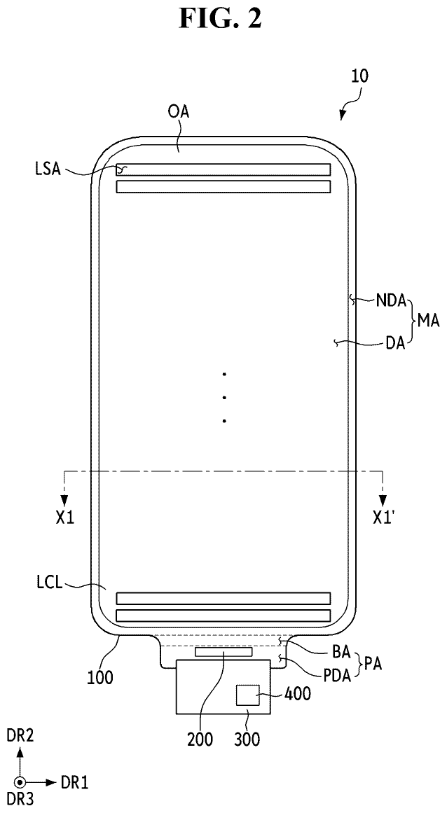

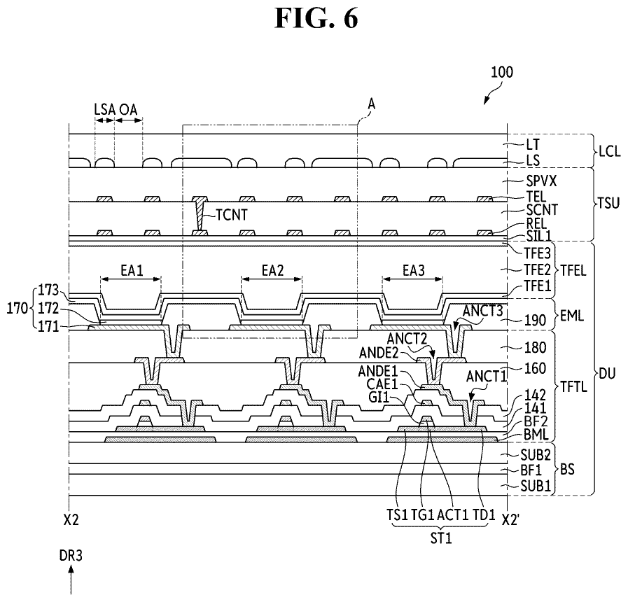

FIG. 1 is a perspective view of a display device 10 according to an embodiment. FIG. 2 is a plan view of the display device 10 according to the embodiment. As used herein, the plan view is a view in a thickness direction (i.e., third direction DR3) of the display device 100 (e.g., substrate SUB1 in FIG. 6).

Referring to FIGS. 1 and 2, the display device 10 is a device for displaying moving images or still images. The display device 10 may be used as a display screen in portable electronic devices such as mobile phones, smartphones, tablet personal computers (PCs), smart watches, watch phones, mobile communication terminals, electronic notebooks, electronic books, portable multimedia players (PMPs), navigation devices and ultra-mobile PCs (UMPCs), as well as in various products such as vehicles, televisions, notebook computers, monitors, billboards, and Internet of things (IoT) devices.

In some embodiments, when the display device 10 is used as a display screen of a vehicle, it may be a vehicle display. The vehicle display may provide a user with information about driving information and status information of the vehicle but also various service information such as convenience functions and media information. When the display device 10 includes an input device such as a touch panel, the user may operate various functions such as the vehicle's driving mode and convenience functions through the display device 10.

The display device 10 may be any one of an organic light emitting display device, a liquid crystal display device, a plasma display device, a field emission display device, an electrophoretic display device, an electrowetting display device, a quantum dot light emitting display device, and a micro-light emitting diode display device. A case where the display device 10 is an organic light emitting display device will be mainly described below, but the present disclosure is not limited thereto.

The display device 10 according to the embodiment may include a display panel 100, a display driver circuit 250, a circuit board 300, and a touch driver circuit 400.

The display panel 100 may include a plurality of pixels PX arranged in a first direction DR1 and a second direction DR2. Each of the pixels PX may have a rectangular, square, or rhombic planar shape. For example, as illustrated in the drawings, each of the pixels PX may have a square planar shape. However, the present disclosure is not limited thereto, and each of the pixels PX may also have various shapes such as a polygonal shape, a circular shape, and an oval shape in a plan view.

In the drawings, the first direction DR1 and the second direction DR2 are horizontal directions and intersect each other. For example, the first direction DR1 and the second direction DR2 may be orthogonal to each other. In addition, a third direction DR3 may be a vertical direction intersecting the first direction DR1 and the second direction DR2, for example, orthogonal to the first direction DR1 and the second direction DR2. In the present specification, a direction indicated by each of the first through third directions DR1 through DR3 in the drawings may be referred to as one side, and the opposite direction may be referred to as the other side. If not specifically specified, each of the first through third directions DR1 through DR3 may include both sides. Unless otherwise defined, in the present specification, a direction indicated by an arrow of each of the first through third directions DR1 through DR3 may be referred to as one side, and the opposite direction may be referred to as the other side. In addition, in the present specification, “on”, “upper side”, “above”, “top”, and “upper surface” refer to a direction in which the arrow of the third direction DR3 points in the drawings, and “under”, “lower side”, “below”, “bottom”, and “lower surface” refer to a direction opposite to the direction in which the arrow of the third direction DR3 points in the drawings.

The display panel 100 may include a main area MA and a protruding area PA protruding from a side of the main area MA.

The main area MA may be shaped like a rectangular plane having short sides in the first direction DR1 and long sides in the second direction DR2 intersecting the first direction DR1. Each corner where a short side extending in the first direction DR1 meets a long side extending in the second direction DR2 may be rounded to have a predetermined curvature or may be right-angled. The planar shape of the display device 10 is not limited to a quadrangular shape, but may also be another polygonal shape, a circular shape, or an oval shape. The main area MA may be formed to be flat. However, the present disclosure is not limited thereto, and the main area MA may also include a curved portion formed at left and right ends thereof in another embodiment. In this case, the curved portion may have a constant curvature or a varying curvature.

The main area MA may include a display area DA where pixels are formed to display an image and a non-display area NDA located around the display area DA.

In the display area DA, not only pixels, but also scan lines, data lines and power lines connected to the pixels may be disposed. When the main area MA includes a curved portion, the display area DA may be disposed in the curved portion. In this case, an image of the display panel 100 may also be seen in the curved portion.

The non-display area NDA may be defined as an area extending from the outside of the display area DA to edges of the display panel 100. A scan driver for transmitting scan signals to the scan lines and link lines connecting the data lines and the display driver circuit 250 may be disposed in the non-display area NDA.

The protruding area PA may protrude from a side of the main area MA. For example, the protruding area PA may protrude from a lower side of the main area MA as illustrated in FIG. 2. A length of the protruding area PA in the first direction DR1 may be smaller than a length of the main area MA in the first direction DR1.

The protruding area PA may include a bending area BA and a pad area PDA. In this case, the pad area PDA may be disposed on a side of the bending area BA, and the main area MA may be disposed on the other side of the bending area BA. For example, the pad area PDA may be disposed on a lower side of the bending area BA, and the main area MA may be disposed on an upper side of the bending area BA.

The display panel 100 may be formed to be flexible so that it can be curved, bent, folded, or rolled. Therefore, the display panel 100 can be bent in the bending area BA in a thickness direction, that is, the third direction DR3. In this case, a surface of the pad area PDA of the display panel 100 faces upward before the display panel 100 is bent. However, after the display panel 100 is bent, the surface of the pad area PDA of the display panel 100 faces downward. Accordingly, the pad area PDA may be disposed under the main area MA and overlapped by the main area MA.

Pads electrically connected to the display driver circuit 250 and the circuit board 300 may be disposed on the pad area PDA of the display panel 100.

The display driver circuit 250 outputs signals and voltages for driving the display panel 100. For example, the display driver circuit 250 may supply data voltages to the data lines. In addition, the display driver circuit 250 may supply power supply voltages to the power lines and supply scan control signals to the scan driver. The display driver circuit 250 may be formed as an integrated circuit and mounted on the pad area PDA of the display panel 100 using a chip on glass (COG) method, a chip on plastic (COP) method, or an ultrasonic bonding method. However, the present disclosure is not limited thereto. For another example, the display driver circuit 250 may also be mounted on the circuit board 300.

The pads may include display pads electrically connected to the display driver circuit 250 and touch pads electrically connected to touch lines.

The circuit board 300 may be attached onto the pads using an anisotropic conductive film. Therefore, lead lines of the circuit board 300 may be electrically connected to the pads. The circuit board 300 may be a flexible printed circuit board, a printed circuit board, or a flexible film such as a chip on film.

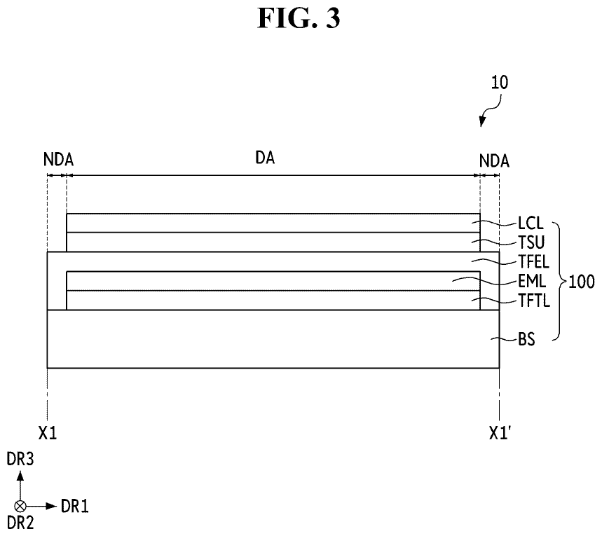

The touch driver circuit 400 may be connected to touch electrodes of a touch sensor layer TSU (see FIG. 3) of the display panel 100. The touch driver circuit 400 transmits driving signals to the touch electrodes of the touch sensor layer TSU (see FIG. 3) and measures capacitance values of the touch electrodes. Each of the driving signals may be a signal having a plurality of driving pulses. The touch driver circuit 400 may not only determine whether a touch has been input based on the capacitance values, but also calculate touch coordinates where the touch has been input.

The touch driver circuit 400 may be disposed on the circuit board 300. The touch driver circuit 400 may be formed as an integrated circuit and mounted on the circuit board 300.

In the display device 10 according to the current embodiment, the display panel 100 may further include a light control layer LCL.

The light control layer LCL may be directly disposed in the main area MA of the display panel 100. For example, the light control layer LCL may be internalized (or embedded) in the display panel 100 and directly disposed in the main area MA of the display panel 100. Since the light control layer LCL is internalized (or embedded) in the display panel 100, there is an advantage in that a thickness and manufacturing cost of the display device 10 can be reduced compared with when a separate light control film is attached.

In some embodiments, the light control layer LCL may be disposed in the display area DA of the main area MA. The light control layer LCL may control a viewing angle of light emitted from a light emitting layer 172 (see FIG. 6) of the display panel 100.

However, the present disclosure is not limited thereto, and a size of the light control layer LCL may also be larger than a size of the display area DA in a plan view. In this case, the light control layer LCL may overlap both the display area DA and the non-display area NDA.

In some embodiments, the light control layer LCL may include a transmissive area OA and non-transmissive areas LSA.

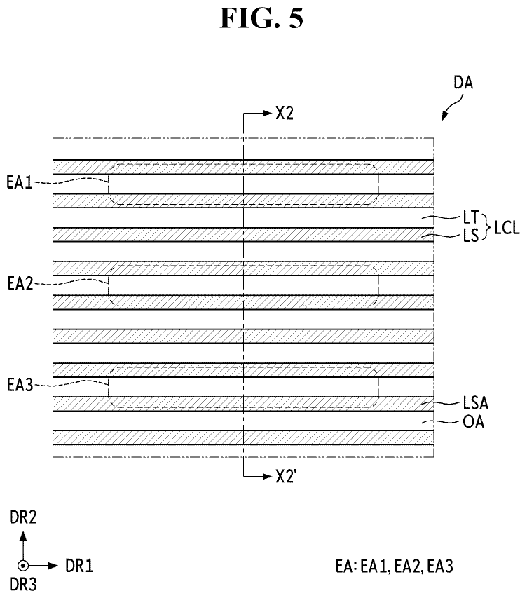

The transmissive area OA may be an area where a light blocking layer LS (see FIG. 5) is not disposed. The transmissive area OA may be an area that transmits light and may extend along the third direction DR3.

The transmissive area OA may have a quadrangular shape in a plan view as illustrated in FIGS. 1 and 2. However, the present disclosure is not limited thereto. The transmissive area OA may also have a circular, oval, or polygonal shape in a plan view. In some embodiments, the shape of the transmissive area OA may generally correspond to the shape of the display panel 100.

The non-transmissive areas LSA may be the remaining areas of the light control layer LCL excluding the transmissive area OA. The non-transmissive areas LSA may be areas where the light blocking layer LS (see FIG. 5) is disposed.

In some embodiments, the non-transmissive areas LSA may extend in the first direction DR1 or the second direction DR2. For example, as illustrated in FIG. 1, the non-transmissive areas LSA may extend in the first direction DR1 and may be disposed along the second direction DR2. For another example, the non-transmissive areas LSA may extend in the second direction DR2 and may be disposed along the first direction DR1. For another example, some of the non-transmissive areas LSA may extend in the first direction DR1 and be disposed along the second direction DR2, but the others of the non-transmissive areas LSA may extend in the second direction DR2 and be disposed along the first direction DR1.

In an embodiment, when the non-transmissive areas LSA are disposed along the second direction DR2 as illustrated in FIG. 1, a viewing angle can be controlled in the second direction DR2. In an embodiment, when the non-transmissive areas LSA are disposed along the first direction DR1, the viewing angle can be controlled in the first direction DR1. In the display device 10 according to the current embodiment, the arrangement and shapes of the transmissive area OA and the non-transmissive areas LSA can be variously changed according to the desirable viewing angle control direction.

Although the transmissive area OA surrounds the non-transmissive areas LSA in the drawings, the present disclosure is not limited thereto. In some embodiments, the transmissive area OA may include a plurality of transmissive areas OA, and the transmissive areas OA may extend in the same direction as the non-transmissive areas LSA so that the transmissive areas OA and the non-transmissive areas LSA are alternately disposed with each other. For example, when the non-transmissive areas LSA extend in the first direction DR1 as in FIG. 1, the transmissive areas OA may extend in the first direction DR1 and may be alternately disposed with the non-transmissive areas LSA in the second direction DR2.

The light control layer LCL may include the light blocking layer LS (see FIG. 5) that blocks light emitted from the light emitting layer 172 (see FIG. 6) of the display panel 100 and a light transmitting layer LT (see FIG. 5) that transmits the light. The detailed structure of the light control layer LCL will be described later with reference to FIG. 5, etc.

FIG. 3 is a schematic cross-sectional view of the display device 10 taken along line X1-X1′ of FIG. 2.

Referring to FIG. 3, the display device 10 may include the display panel 100 having the light control layer LCL internalized (or embedded) therein. The display panel 100 may include a base member BS, a thin-film transistor layer TFTL, a light emitting element layer EML, a thin-film encapsulation layer TFEL, the touch sensor layer TSU, and the light control layer LCL.

The base member BS may include a substrate. The substrate may be made of an insulating material such as glass, quartz, or polymer resin. The polymer material may be, for example, polyethersulphone (PES), polyacrylate (PA), polyarylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (CAT), cellulose acetate propionate (CAP), or a combination thereof. Alternatively, the substrate may include a metal material.

The substrate may be a rigid substrate or a flexible substrate that can be bent, folded, or rolled. When the substrate is a flexible substrate, it may be made of, but not limited to, polyimide (PI).

The thin-film transistor layer TFTL may be disposed on the base member BS. In the thin-film transistor layer TFTL, not only thin-film transistors of pixels, but also scan lines, data lines, power lines, scan control lines, and link lines connecting pads and the data lines may be formed. Each of the thin-film transistors may include a gate electrode, a semiconductor layer, a source electrode, and a drain electrode.

The thin-film transistor layer TFTL may be disposed in the display area DA and the non-display area NDA. Specifically, the thin-film transistors of the pixels, the scan lines, the data lines, and the power lines of the thin-film transistor layer TFTL may be disposed in the display area DA. The scan control lines and the link lines of the thin-film transistor layer TFTL may be disposed in the non-display area NDA.

The light emitting element layer EML may be disposed on the thin-film transistor layer TFTL. The light emitting element layer EML may include pixels, each including a first electrode, a light emitting layer and a second electrode, and a pixel defining layer defining the pixels. The light emitting layer may be an organic light emitting layer including an organic material. In this case, the light emitting layer may include a hole transporting layer, an organic light emitting layer, and an electron transporting layer. When a predetermined voltage is applied to the first electrode and a cathode voltage is applied to the second electrode through a thin-film transistor of the thin-film transistor layer TFTL, holes and electrons move to the organic light emitting layer through the hole transporting layer and the electron transporting layer, respectively, and combine together in the organic light emitting layer to emit light. The pixels of the light emitting element layer EML may be disposed in the display area DA.

The thin-film encapsulation layer TFEL may be disposed on the light emitting element layer EML. The thin-film encapsulation layer TFEL may prevent oxygen or moisture from permeating into the light emitting element layer EML. To this end, the thin-film encapsulation layer TFEL may include at least one inorganic layer. The inorganic layer may be, but is not limited to, a silicon nitride layer, a silicon oxynitride layer, a silicon oxide layer, a titanium oxide layer, or an aluminum oxide layer. In addition, the thin-film encapsulation layer TFEL may protect the light emitting element layer EML from foreign substances such as dust. To this end, the thin-film encapsulation layer TFEL may include at least one organic layer. The organic layer may be, but is not limited to, acryl resin, epoxy resin, phenolic resin, polyamide resin, or polyimide resin.

The thin-film encapsulation layer TFEL may be disposed in both the display area DA and the non-display area NDA. Specifically, the thin-film encapsulation layer TFEL may cover the light emitting element layer EML of the display area DA and the non-display area NDA and cover the thin-film transistor layer TFTL of the non-display area NDA.

The touch sensor layer TSU may be disposed on the thin-film encapsulation layer TFEL. Since the touch sensor layer TSU is directly disposed on the thin-film encapsulation layer TFEL, there is an advantage in that the thickness of the display device 10 can be reduced compared with when a separate touch panel including the touch sensor layer TSU is attached onto the thin-film encapsulation layer TFEL.

The touch sensor layer TSU may include touch electrodes for sensing a user's touch in a capacitive manner and touch lines connecting pads and the touch electrodes. For example, the touch sensor layer TSU may sense a user's touch in a self-capacitance manner or a mutual capacitance manner.

The touch electrodes of the touch sensor layer TSU may be disposed in a touch sensor area overlapping the display area DA. The touch lines of the touch sensor layer TSU may be disposed in a touch peripheral area overlapping the non-display area NDA.

The light control layer LCL may be disposed on the touch sensor layer TSU. The light control layer LCL may be disposed to overlap the display area DA. The light control layer LCL may absorb or block light that travels outside a certain angle with respect to the third direction DR3 among light emitted from the light emitting element layer EML. That is, the light control layer LCL can control the viewing angle.

Although not illustrated in the drawing, the display device 10 may further include a cover window. The cover window may be additionally disposed on the light control layer LCL. In this case, the light control layer LCL and the cover window may be attached by a transparent adhesive member such as an optically clear adhesive (OCA) film.

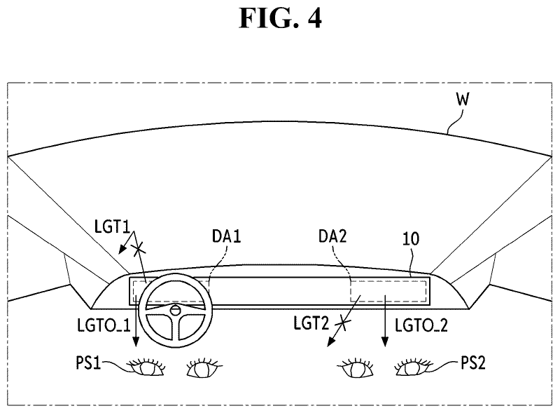

FIG. 4 is a diagram of a case where the display device 10 according to the embodiment is applied to a vehicle.

Referring to FIG. 4, the display device 10 according to the embodiment may be, for example, a display device applied to a vehicle. The vehicle may include a body that forms the exterior of the vehicle and an interior space defined by the body. The body may include a windshield W that protects a driver PS1 and a passenger PS2 from the outside and provides a view to the driver PS1. The display device 10 may be provided in the interior space as illustrated in the drawing.

In some embodiments, the display device 10 may be disposed on a dashboard provided in the interior space. For example, as illustrated in FIG. 4, the display device 10 may extend from a dashboard located in front of a driver's seat to a dashboard located in front of a passenger seat. For example, the display device 10 may be an integrated display connected from the dashboard located in front of the driver's seat to the dashboard located in front of the passenger seat.

In this case, the display device 10 may include a first display area DA1 located in front of the driver's seat and a second display area DA2 located in front of the passenger seat. The first display area DA1 may be disposed on the dashboard in front of the driver's seat to provide speed information, etc. to the driver PS1, and the second display area DA2 may be disposed on the dashboard in front of the passenger seat to provide entertainment information, etc. to the passenger PS2. Although not illustrated in the drawing, a third display area may be further included between the first display area DA1 and the second display area DA2.

For another example, the display device 10 may be disposed on each of the dashboard in front of the driver's seat and the dashboard in front of the passenger seat. For example, a first display device may be disposed on the dashboard in front of the driver's seat, and a second display device may be disposed on the dashboard in front of the passenger seat.

The driver PS1 may recognize (or view) a display screen of the display device 10 through light LGT0_1 emitted from the display device 10 in front of the driver's seat toward the driver PS1. However, some (LGT1) of the light emitted from the display device 10 in front of the driver's seat may be reflected by the surrounding windshield W to the driver PS1. In this case, an image reflected in the windshield W may interfere with the driving of the driver PS1. On the other hand, the display device 10 according to the embodiment adjusts the viewing angle, especially vertical viewing angle, of the light emitted from the display device 10 in a forward direction (a direction facing the driver PS1 directly), thereby preventing some (LGT1) of the light emitted from the display device 10 in front of the driver's seat from being reflected by the surrounding windshield W to the driver PS1.

The passenger PS2 may recognize (or view) the display screen of the display device 10 through light LGT0_2 emitted from the display device 10 in front of the passenger seat toward the passenger PS2. However, some (LGT2) of the light emitted from the display device 10 in front of the passenger seat may be provided toward the driver PS1. In this case, when the vehicle is in operation, the viewing of the driver PS1 may be restricted for reasons such as safety. However, the display device 10 according to the embodiment may adjust the viewing angle, especially horizontal viewing angle, of the light emitted from the display device 10 in the forward direction (a direction facing the passenger PS2 directly), thereby preventing some (LGT2) of the light emitted from the display device 10 in front of the passenger seat from being provided to the driver PS1.

In the drawing, the display device 10 in front of the driver's seat adjusts the vertical viewing angle, and the display device 10 in front of the passenger seat adjusts the horizontal viewing angle. However, the present disclosure is not limited thereto. For another example, the display device 10 in front of the driver's seat may also adjust the horizontal viewing angle, and the display device 10 in front of the passenger seat may also adjust the vertical viewing angle. For another example, each of the display device 10 in front of the driver's seat and the display device 10 in front of the passenger seat may adjust both the vertical viewing angle and the horizontal viewing angle.

The viewing angle may be adjusted through the light control layer LCL. The viewing angle may be limited to a predetermined angle range through the light control layer LCL. For example, when a virtual line facing the driver PS1 or the passenger PS2 and extending in a direction perpendicular to a display surface of the display device 10 is taken as a normal line, the viewing angle may be an angle within 35 degrees from the normal line. In some embodiments, the angle within 35 degrees from the normal line may be defined as an effective viewing angle, but the present disclosure is not limited thereto.

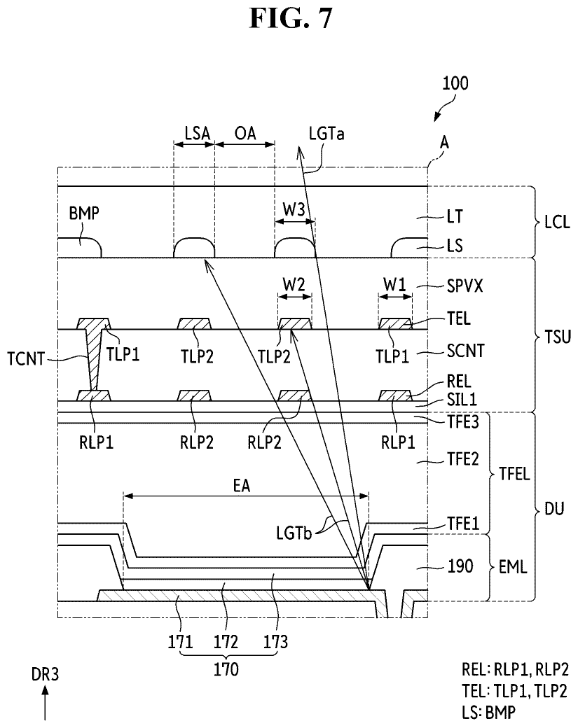

FIG. 5 is a plan view of a part of a display area DA according to an embodiment. FIG. 6 is a cross-sectional view taken along line X2-X2′ of FIG. 5. FIG. 7 is an enlarged view of area A of FIG. 6.

Referring to FIGS. 5 through 7, the display area DA of the display device 10 may include a plurality of emission areas EA. Each of the emission areas EA may be an area where light emitted from a light emitting element 170 is output. The emission areas EA may be defined by a bank 190. For example, each of the emission areas EA may be an area overlapping a light emitting layer 172 disposed within an opening of the bank 190. Each of the emission areas EA may be an area in which a first light emitting electrode 171, the light emitting layer 172, and a second light emitting electrode 173 are sequentially stacked while overlapping each other in a plan view.

In some embodiments, the emission areas EA may include a first emission area EA1, a second emission area EA2, and a third emission area EA3. Although three types of emission areas EA are included in the display area DA in the drawings, the present disclosure is not limited thereto, and more or less than three types may also be included in another embodiment.

The first emission area EA1 may emit light of a first color, the second emission area EA2 may emit light of a second color, and the third emission area EA3 may emit light of a third color. The light of the first color may be light in a red wavelength band, the light of the second color may be light in a green wavelength band, and the light of the third color may be light in a blue wavelength band. The red wavelength band may be a wavelength band of about 600 to 750 nanometers (nm), the green wavelength band may be a wavelength band of about 480 to 560 nm, and the blue wavelength band may be a wavelength band of about 370 to 460 nm, but the present disclosure is not limited thereto.

Each of the first through third emission areas EA1 through EA3 may have a rectangular, square, or rhombic planar shape. For example, as illustrated in the drawings, each of the first through third emission areas EA1 through EA3 may have a rectangular shape with rounded corners, but the present disclosure is not limited thereto.

In an embodiment, the areas of the first through third emission areas EA1 through EA3 may be the same. The first through third emission areas EA1 through EA3 may extend in the first direction DR1 and may be disposed side by side with each other along the second direction DR2.

In an embodiment, the areas of the first through third emission areas EA1 through EA3 may be different from each other. The first through third emission areas EA1 through EA3 may extend in the second direction DR2 and may be disposed side by side with each other along the first direction DR1.

The number, shape, arrangement, etc. of the emission areas EA are not limited to those illustrated in the drawings.

In FIG. 5, a case where the transmissive area OA and the non-transmissive areas LSA extend in the first direction DR1 as in the display device 10 according to the embodiment of FIG. 1 is illustrated as an example. However, as described above, the direction in which the transmissive area OA and the non-transmissive areas LSA extend is not limited to the first direction DR1.

The transmissive area OA may be an area where the light blocking layer LS of the light control layer LCL is not disposed. The non-transmissive areas LSA may be areas where the light blocking layer LS of the light control layer LCL is disposed.

The emission areas EA of the display area DA may overlap the transmissive area OA and the non-transmissive areas LSA in the third direction DR3. For example, the first through third emission areas EA1 through EA3 may overlap the transmissive area OA and the non-transmissive areas LSA in the third direction DR3.

The structure of the display panel 100 will be described with reference to FIG. 6.

The display panel 100 may include a display layer DU, the touch sensor layer TSU, and the light control layer LCL. The display layer DU may include the base member BS, the thin-film transistor layer TFTL, the light emitting element layer EML, and the thin-film encapsulation layer TFEL.

The base member BS may include a first substrate SUB1, a first buffer layer BF1 disposed on the first substrate SUB1, and a second substrate SUB2 disposed on the first buffer layer BF1.

The first substrate SUB1 and the second substrate SUB2 may be made of an insulating material such as glass, quartz, or polymer resin. The polymer material may be, for example, polyethersulphone (PES), polyacrylate (PA), polyarylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (CAT), cellulose acetate propionate (CAP), or a combination thereof. Alternatively, the first substrate SUB1 may include a metal material.

The first substrate SUB1 and the second substrate SUB2 may be rigid substrates or flexible substrates that can be bent, folded, or rolled. When the first substrate SUB1 and the second substrate SUB2 are flexible substrates, they may be made of, but not limited to, polyimide (PI).

The first buffer layer BF1 is a layer for protecting first thin-film transistors ST1 and light emitting layers 172 from moisture introduced through the first substrate SUB1 and the second substrate SUB2 which are vulnerable to moisture penetration. The first buffer layer BF1 may be composed of a plurality of inorganic layers stacked alternately. For example, the first buffer layer BF1 may be a multilayer in which one or more inorganic layers selected from a silicon nitride layer, a silicon oxynitride layer, a silicon oxide layer, a titanium oxide layer, and an aluminum oxide layer are alternately stacked.

The thin-film transistor layer TFTL may include bottom metal layers BML, a second buffer layer BF2, the first thin-film transistors ST1, first gate insulating layers GI1, a first interlayer insulating layer 141, first capacitor electrodes CAE1, a second interlayer insulating layer 142, first anode connection electrodes ANDE1, a first organic layer 160, second anode connection electrodes ANDE2, and a second organic layer 180.

The bottom metal layers BML may be disposed on the second substrate SUB2. The bottom metal layers BML may overlap first active layers ACT1 of the first thin-film transistors ST1 in the third direction DR3 to prevent leakage current from occurring when light is incident on the first active layers ACT1 of the first thin-film transistors ST1. Each of the bottom metal layers BML may be a single layer or a multilayer made of any one or more of molybdenum (Mo), aluminum (Al), chromium (Cr), gold (Au), titanium (Ti), nickel (Ni), neodymium (Nd), copper (Cu), and alloys thereof.

The second buffer layer BF2 may be disposed on the bottom metal layers BML. The second buffer layer BF2 is a layer for protecting the first thin-film transistors ST1 and the light emitting layers 172 from moisture introduced through the first substrate SUB1 and the second substrate SUB2 which are vulnerable to moisture penetration. The second buffer layer BF2 may be composed of a plurality of inorganic layers stacked alternately. For example, the second buffer layer BF2 may be a multilayer in which one or more inorganic layers selected from a silicon nitride layer, a silicon oxynitride layer, a silicon oxide layer, a titanium oxide layer, and an aluminum oxide layer are alternately stacked.

The first active layers ACT1 of the first thin-film transistors ST1 may be disposed on the second buffer layer BF2. The first active layers ACT1 of the first thin-film transistors ST1 include polycrystalline silicon, monocrystalline silicon, low-temperature polycrystalline silicon, amorphous silicon, or an oxide semiconductor. The first active layers ACT1 of the first thin-film transistors ST1 exposed without being covered by the first gate insulating layers GI1 may be doped with impurities or ions to have conductivity. Accordingly, first source electrodes TS1 and first drain electrodes TD1 of the first active layers ACT1 of the first thin-film transistors ST1 may be formed.

The first gate insulating layers GI1 may be disposed on the first active layers ACT1 of the first thin-film transistors ST1. In FIG. 5, the first gate insulating layers GI1 are disposed between first gate electrodes TG1 and the first active layers ACT1 of the first thin-film transistors ST1. However, the present disclosure is not limited thereto. The first gate insulating layers GI1 may also be disposed between the first interlayer insulating layer 141 and the first active layers ACT1 and between the first interlayer insulating layer 141 and the second buffer layer BF2 in another embodiment. Each of the first gate insulating layers GI1 may be made of an inorganic layer, for example, a silicon nitride layer, a silicon oxynitride layer, a silicon oxide layer, a titanium oxide layer, or an aluminum oxide layer.

The first gate electrodes TG1 of the first thin-film transistors ST1 may be disposed on the first gate insulating layers GI1. The first gate electrodes TG1 of the first thin-film transistors ST1 may overlap the first active layers ACT1 in the third direction DR3. Each of the first gate electrodes TG1 of the first thin-film transistors ST1 may be a single layer or a multilayer made of any one or more of molybdenum (Mo), aluminum (Al), chromium (Cr), gold (Au), titanium (Ti), nickel (Ni), neodymium (Nd), copper (Cu), and alloys thereof.

The first interlayer insulating layer 141 may be disposed on the first gate electrodes TG1 of the first thin-film transistors ST1. The first interlayer insulating layer 141 may be made of an inorganic layer, for example, a silicon nitride layer, a silicon oxynitride layer, a silicon oxide layer, a titanium oxide layer, or an aluminum oxide layer. The first interlayer insulating layer 141 may include a plurality of inorganic layers.

The first capacitor electrodes CAE1 may be disposed on the first interlayer insulating layer 141. The first capacitor electrodes CAE1 may overlap the first gate electrodes TG1 of the first thin-film transistors ST1 in the third direction DR3. Since the first interlayer insulating layer 141 has a predetermined dielectric constant, capacitors may be formed by the first capacitor electrodes CAE1, the first gate electrodes TG1, and the first interlayer insulating layer 141 disposed between them. Each of the first capacitor electrodes CAE1 may be a single layer or a multilayer made of any one or more of molybdenum (Mo), aluminum (Al), chromium (Cr), gold (Au), titanium (Ti), nickel (Ni), neodymium (Nd), copper (Cu), and alloys thereof.

The second interlayer insulating layer 142 may be disposed on the first capacitor electrodes CAE1. The second interlayer insulating layer 142 may be made of an inorganic layer, for example, a silicon nitride layer, a silicon oxynitride layer, a silicon oxide layer, a titanium oxide layer, or an aluminum oxide layer. The second interlayer insulating layer 142 may include a plurality of inorganic layers.

The first anode connection electrodes ANDE1 may be disposed on the second interlayer insulating layer 142. Each of the first anode connection electrodes ANDE1 may be connected to the first drain electrode TD1 of a first thin-film transistor ST1 through a first anode contact hole ANCT1 penetrating the first interlayer insulating layer 141 and the second interlayer insulating layer 142 to expose the first drain electrode TD1 of the first thin-film transistor ST1. Each of the first anode connection electrodes ANDE1 may be a single layer or a multilayer made of any one or more of molybdenum (Mo), aluminum (Al), chromium (Cr), gold (Au), titanium (Ti), nickel (Ni), neodymium (Nd), copper (Cu), and alloys thereof.

The first organic layer 160 for planarization may be disposed on the first anode connection electrodes ANDE1. The first organic layer 160 may be made of an organic layer such as acryl resin, epoxy resin, phenolic resin, polyamide resin, or polyimide resin.

The second anode connection electrodes ANDE2 may be disposed on the first organic layer 160. Each of the second anode connection electrodes ANDE2 may be connected to a first anode connection electrode ANDE1 through a second anode contact hole ANCT2 penetrating the first organic layer 160 to expose the first anode connection electrode ANDE1. Each of the second anode connection electrodes ANDE2 may be a single layer or a multilayer made of any one or more of molybdenum (Mo), aluminum (Al), chromium (Cr), gold (Au), titanium (Ti), nickel (Ni), neodymium (Nd), copper (Cu), and alloys thereof.

The second organic layer 180 may be disposed on the second anode connection electrodes ANDE2. The second organic layer 180 may be made of an organic layer such as acryl resin, epoxy resin, phenolic resin, polyamide resin, or polyimide resin.

In FIG. 6, the first thin-film transistors ST1 are formed in a top gate structure in which the first gate electrodes TG1 are located above the first active layers ACT1. However, the present disclosure is not limited thereto. The first thin-film transistors TFT1 may also be formed in a bottom gate structure in which the first gate electrodes TG1 are located below the first active layers ACT1 or a double gate structure in which the first gate electrodes TG1 are located both above and below the first active layers ACT1 in another embodiment.

The light emitting element layer EML may be disposed on the second organic layer 180. The light emitting element layer EML may include light emitting elements 170 and the bank 190. Each of the light emitting elements 170 may include a first light emitting electrode 171, a light emitting layer 172, and a second light emitting electrode 173.

The first light emitting electrode 171 may be formed on the second organic layer 180. The first light emitting electrode 171 may be connected to a second anode connection electrode ANDE2 through a third anode contact hole ANCT3 penetrating the second organic layer 180 to expose the second anode connection electrode ANDE2.

In a top emission structure in which light is emitted from the light emitting layer 172 toward the second light emitting electrode 173, the first light emitting electrode 171 may be made of a metal material having high reflectivity, such as a stacked structure (Ti/Al/Ti) of aluminum and titanium, a stacked structure (ITO/AI/ITO) of aluminum and indium tin oxide, an APC alloy, or a stacked structure (ITO/APC/ITO) of an APC alloy and indium tin oxide. The APC alloy is an alloy of silver (Ag), palladium (Pd), and copper (Cu).

The bank 190 may be formed on the second organic layer 180 to separate the first light emitting electrode 171 from another first light emitting electrode 171 so as to define each emission area EA. The bank 190 may defines openings therein, each exposing at least a portion of an upper surface of the first light emitting electrode 171. The bank 190 may be formed to cover edges of the first light emitting electrode 171. The bank 190 may be made of an organic layer such as acryl resin, epoxy resin, phenolic resin, polyamide resin, or polyimide resin.

Each emission area EA is an area in which the first light emitting electrode 171, the light emitting layer 172, and the second light emitting electrode 173 are sequentially stacked so that holes from the first light emitting electrode 171 and electrons from the second light emitting electrode 173 are recombined with each other in the light emitting layer 172 to emit light. The emission areas EA may be defined by the openings of the bank 190.

The light emitting layer 172 is formed on the first light emitting electrode 171 and the bank 190. The light emitting layer 172 may be disposed in each opening of the bank 190, but the present disclosure is not limited thereto. The light emitting layer 172 may include an organic material to emit light of a predetermined color. For example, the light emitting layer 172 may include a hole transporting layer, an organic material layer, and an electron transporting layer.

The second light emitting electrode 173 may be disposed on the light emitting layer 172. The second light emitting electrode 173 may be formed to cover the light emitting layer 172. The second light emitting electrode 173 may be a common layer formed commonly in all emission areas EA. Although not illustrated in the drawings, in some embodiments, a capping layer may be formed on the second light emitting electrode 173.

In the top emission structure, the second light emitting electrode 173 may be made of a transparent conductive material (TCO) that can transmit light, such as indium tin oxide (ITO) or indium zinc oxide (IZO), or a semi-transmissive conductive material such as magnesium (Mg), silver (Ag) or an alloy of Mg and Ag. When the second light emitting electrode 173 is made of a semi-transmissive conductive material, light output efficiency may be increased by a microcavity.

The thin-film encapsulation layer TFEL may be disposed on the second light emitting electrode 173. The thin-film encapsulation layer TFEL may include at least one inorganic layer to prevent oxygen or moisture from permeating into the light emitting element layer EML. In addition, the thin-film encapsulation layer TFEL may include at least one organic layer to protect the light emitting element layer EML from foreign substances such as dust. For example, the thin-film encapsulation layer TFEL may include a first encapsulation layer TFE1, a second encapsulation layer TFE2, and a third encapsulation layer TFE3.

The first encapsulation layer TFE1 (e.g., a first inorganic encapsulation layer) may be disposed on the second light emitting electrode 173. The first encapsulation layer TFE1 may be a single-layer or multilayer inorganic layer. The first encapsulation layer TFE1 may be a single layer or a multilayer in which one or more inorganic layers selected from a silicon nitride layer, a silicon oxynitride layer, a silicon oxide layer, a titanium oxide layer, and an aluminum oxide layer are alternately stacked.

The second encapsulation layer TFE2 (e.g., a first organic encapsulation layer) may be disposed on the first encapsulation layer TFE1. The second encapsulation layer TFE2 may be a single-layer or multilayer organic layer. The second encapsulation layer TFE2 may include a polymer-based material. The polymer-based material may include polyethylene terephthalate, polyethylene naphthalate, polycarbonate, polyimide, polyethylene sulfonate, polyoxymethylene, polyarylate, hexamethyldisiloxane (HMDSO), acrylic resin (e.g., polymethyl methacrylate, polyacrylic acid, etc.), or any combination thereof.

The third encapsulation layer TFE3 (e.g., a second inorganic encapsulation layer) may be disposed on the second encapsulation layer TFE2. The third encapsulation layer TFE3 may be a single-layer or multilayer inorganic layer. The third encapsulation layer TFE3 may include the same material as the first encapsulation layer TFE1. For example, the third encapsulation layer TFE3 may be a single layer or a multilayer in which one or more inorganic layers selected from a silicon nitride layer, a silicon oxynitride layer, a silicon oxide layer, a titanium oxide layer, and an aluminum oxide layer are alternately stacked.

The touch sensor layer TSU may be disposed on the thin-film encapsulation layer TFEL. The touch sensor layer TSU may include a plurality of touch electrodes for sensing a user's touch in a capacitive manner and touch lines connecting the touch electrodes and a touch driver. For example, the touch sensor layer TSU may sense a user's touch in a mutual capacitance manner or a self-capacitance manner.

The touch sensor layer TSU may include a first touch insulating layer SIL1, a first touch conductive layer REL, a second touch insulating layer SCNT, a second touch conductive layer TEL, and a third touch insulating layer SPVX.

The first touch insulating layer SIL1 may be disposed on the thin-film encapsulation layer TFEL. The first touch insulating layer SIL1 may have insulating and optical functions. The first touch insulating layer SIL1 may include at least one inorganic layer. For example, the first touch insulating layer SIL1 may be an inorganic layer including at least one of a silicon nitride layer, a silicon oxynitride layer, a silicon oxide layer, a titanium oxide layer, and an aluminum oxide layer. Optionally, the first touch insulating layer SIL1 may be omitted.

The first touch conductive layer REL may be disposed on the first touch insulating layer SIL1. The first touch conductive layer REL may be formed as a single layer of molybdenum (Mo), titanium (Ti), copper (Cu), aluminum (Al) or indium tin oxide (ITO) or may be formed as a stacked structure (Ti/Al/Ti) of aluminum and titanium, a stacked structure (ITO/Al/ITO) of aluminum and indium tin oxide, an APC alloy, or a stacked structure (ITO/APC/ITO) of an APC alloy and indium tin oxide.

The second touch insulating layer SCNT may be disposed on the first touch conductive layer REL and the first touch insulating layer SIL1. The second touch insulating layer SCNT may cover the first touch conductive layer REL and the first touch insulating layer SIL1. The second touch insulating layer SCNT may have insulating and optical functions. The second touch insulating layer SCNT may include at least one organic layer. For example, the second touch insulating layer SCNT may include at least any one of acryl resin, epoxy resin, phenolic resin, polyamide resin, and polyimide resin.

The second touch conductive layer TEL may be disposed on the second touch insulating layer SCNT. The second touch conductive layer TEL may be formed as a single layer of molybdenum (Mo), titanium (Ti), copper (Cu), aluminum (Al) or indium tin oxide (ITO) or may be formed as a stacked structure (Ti/Al/Ti) of aluminum and titanium, a stacked structure (ITO/Al/ITO) of aluminum and indium tin oxide, an APC alloy, or a stacked structure (ITO/APC/ITO) of an APC alloy and indium tin oxide.

In some embodiments, the second touch conductive layer TEL may be connected to the first touch conductive layer REL through a touch contact hole TCNT penetrating the second touch insulating layer SCNT.

The third touch insulating layer SPVX may be disposed on the second touch conductive layer TEL and the second touch insulating layer SCNT. The third touch insulating layer SPVX may cover the second touch conductive layer TEL and the second touch insulating layer SCNT. The third touch insulating layer SPVX may have insulating and optical functions. The third touch insulating layer SPVX may include at least one organic layer. For example, the third touch insulating layer SPVX may include at least any one of acryl resin, epoxy resin, phenolic resin, polyamide resin, and polyimide resin.

In the display device 10 according to the current embodiment, the touch sensor layer TSU may not only sense a user's touch, but also control the viewing angle of light emitted from the light emitting layer 172, together with the light control layer LCL. For example, if the light emitted from the light emitting layer 172 travels at a predetermined angle or less with respect to the third direction DR3, it may be output to the outside. On the other hand, if the light emitted from the light emitting layer 172 travels at more than the predetermined angle with respect to the third direction DR3, it may not be output to the outside by being absorbed or blocked by the first touch conductive layer REL and the second touch conductive layer TEL of the touch sensor layer TSU.

The light control layer LCL may be disposed on the touch sensor layer TSU. The light control layer LCL may control the viewing angle of light emitted from the light emitting layer 172. For example, if the light emitted from the light emitting layer 172 travels at a predetermined angle or less with respect to the third direction DR3, it may be output to the outside. On the other hand, if the light emitted from the light emitting layer 172 travels at more than the predetermined angle with respect to the third direction DR3, it may not be output to the outside by being absorbed or blocked by the light blocking layer LS.

The light control layer LCL may include the light blocking layer LS and the light transmitting layer LT.

The light blocking layer LS may be disposed on the touch sensor layer TSU. For example, the light blocking layer LS may be disposed on the third touch insulating layer SPVX. The light blocking layer LS may absorb or block light emitted from the light emitting layer 172. The light blocking layer LS may include a light-blocking organic material. For example, the light blocking layer LS may be a photosensitive resin that can absorb or block light and may include an organic material including an organic black pigment such as carbon black.

The light blocking layer LS may be disposed in the non-transmissive areas LSA. As illustrated in FIG. 5, the light blocking layer LS may be disposed alternately with the light transmitting layer LT in the first direction DR1 or the second direction DR2.

The light transmitting layer LT may be disposed on the light blocking layer LS and the third touch insulating layer SPVX. The light transmitting layer LT may cover the light blocking layer LS and the third touch insulating layer SPVX. The light transmitting layer LT may transmit light emitted from the light emitting layer 172. The light transmitting layer LT may include a transparent organic material. For example, the light transmitting layer LT may include an organic layer such as acryl resin, epoxy resin, phenolic resin, polyamide resin, or polyimide resin.

The light transmitting layer LT may be disposed in the transmissive area OA. As illustrated in FIG. 5, the light transmitting layer LT may be disposed alternately with the light blocking layer LS in the first direction DR1 or the second direction DR2.

The structure of the touch sensor layer TSU and the light control layer LCL and a viewing angle control method will be described with reference to FIG. 7.

The first touch conductive layer REL may include a plurality of first pattern electrodes RLP1 and RLP2. The first pattern electrodes RLP1 and RLP2 may be spaced apart from each other. The first pattern electrodes RLP1 and RLP2 may include first sub-pattern electrodes RLP1 and second sub-pattern electrodes RLP2. The second sub-pattern electrodes RLP2 may be disposed between the first sub-pattern electrodes RLP1. For example, as illustrated in the drawing, two second sub-pattern electrodes RLP2 may be disposed between two first sub-pattern electrodes RLP1. However, the present disclosure is not limited thereto, and one second sub-pattern electrode RLP2 or three or more second sub-pattern electrodes RLP2 may also be disposed between two first sub-pattern electrodes RLP1 in another embodiment.

The second touch conductive layer TEL may include a plurality of second pattern electrodes TLP1 and TLP2. The second pattern electrodes TLP1 and TLP2 may be spaced apart from each other. The second pattern electrodes TLP1 and TLP2 may include third sub-pattern electrodes TLP1 and fourth sub-pattern electrodes TLP2. The fourth sub-pattern electrodes TLP2 may be disposed between the third sub-pattern electrodes TLP1. For example, as illustrated in the drawing, two fourth sub-pattern electrodes TLP2 may be disposed between two third sub-pattern electrodes TLP1. However, the present disclosure is not limited thereto, and one fourth sub-pattern electrode TLP2 or three or more fourth sub-pattern electrodes TLP2 may also be disposed between two third sub-pattern electrodes TLP1 in another embodiment.

The light blocking layer LS may include a plurality of light blocking patterns BMP. The light blocking patterns BMP may be spaced apart from each other. The light blocking patterns BMP may overlap the first through fourth sub-pattern electrodes RLP1, RLP2, TLP1 and TLP2 in the third direction DR3, respectively.

The first sub-pattern electrodes RLP1 and the third sub-pattern electrodes TLP1 may overlap the bank 190 in the third direction DR3. The second sub-pattern electrodes RLP2 and the fourth sub-pattern electrodes TLP2 may overlap an emission area EA in the third direction DR3. The touch contact hole TCNT may connect a first sub-pattern electrode RLP1 and a third sub-pattern electrode TLP3 to each other. That is, the touch contact hole TCNT may overlap the bank 190 in the third direction DR3.

As illustrated in FIG. 7, first light LGTa may be output to the outside because it travels at a predetermined angle or less with respect to the third direction DR3. On the other hand, second light LGTb may not be output to the outside because it travels at more than the predetermined angle with respect to the third direction DR3 and is thus blocked by the first pattern electrodes RLP1 and RLP2 of the first touch conductive layer REL, the second pattern electrodes TLP1 and TLP2 of the second touch conductive layer TEL, or the light blocking patterns BMP of the light blocking layer LS.

For example, if the first touch conductive layer REL and the second touch conductive layer TEL have a stacked structure of aluminum and titanium (Ti/Al/Ti) in which a thickness of a first layer, i.e., a titanium layer is about 300 angstroms (Å), a thickness of a second layer, i.e., an aluminum layer is about 2500 Å, and a thickness of a third layer, i.e., a titanium layer is about 300 Å, the transmittance of each of the first touch conductive layer REL and the second touch conductive layer TEL for visible light may be about 5%. If visible light passes through both the first touch conductive layer REL and the second touch conductive layer TEL, the final transmittance for the visible light may be about 0.25%. In this way, the first pattern electrodes RLP1 and RLP2 of the first touch conductive layer REL and the second pattern electrodes TLP1 and TLP2 of the second touch conductive layer TEL may function as light blocking members for light traveling at more than a predetermined angle with respect to the third direction DR3, together with the light blocking patterns BMP of the light blocking layer LS.

In the display device 10 according to the current embodiment, the first through fourth sub-pattern electrodes RLP1, RLP2, TLP1 and TLP2 may be touch electrodes for sensing a user's touch. The first through fourth sub-pattern electrodes RLP1, RLP2, TLP1 and TLP2 may receive a driving signal from the touch driver circuit 400 (see FIG. 1) described above with reference to FIG. 1 or provide a sensing signal to the touch driver circuit 400 (see FIG. 1). The first through fourth sub-pattern electrodes RLP1, RLP2, TLP1 and TLP2 may be electrically connected to the touch driver circuit 400 (see FIG. 1) through touch lines.

When all of the first through fourth sub-pattern electrodes RLP1, RLP2, TLP1 and TLP2 function as touch electrodes, widths of the first through fourth sub-pattern electrodes RLP1, RLP2, TLP1 and TLP2 may be substantially equal in order to increase the uniformity of touch sensing and maintain constant touch sensing sensitivity at any point. For example, a width W1 of each third sub-pattern electrode TLP1 may be substantially equal to a width W2 of each fourth sub-pattern electrode TLP2. Although not illustrated in the drawing, a width of each first sub-pattern electrode RLP1 may be substantially equal to a width of each second sub-pattern electrode RLP2 for the same effect.

In some embodiments, the widths of the first through fourth sub-pattern electrodes RLP1, RLP2, TLP1 and TLP2 may each be different from a width W3 of each light blocking pattern BMP. For example, the width W1 of each third sub-pattern electrode TLP1 and the width W2 of each fourth sub-pattern electrode TLP2 may each be smaller than the width W3 of each light blocking pattern BMP. Likewise, although not illustrated in the drawing, the width of each first sub-pattern electrode RLP1 and the width of each second sub-pattern electrode RLP2 may each be smaller than the width W3 of each light blocking pattern BMP.

As the display device 10 has higher resolution, the emission area EA and the bank 190 may become narrower. Accordingly, a distance between the first pattern electrodes RLP1 and RLP2, a distance between the second pattern electrodes TLP1 and TLP2, and a distance between the light blocking patterns BMP may decrease. In addition, the width of each of the first pattern electrodes RLP1 and RLP2, the width of each of the second pattern electrodes TLP1 and TLP2, and the width of each of the light blocking patterns BMP may decrease.

Depending on display process conditions, a minimum width of the first pattern electrodes RLP1 and RLP2 and the second pattern electrodes TLP1 and TLP2 including metal may be smaller than a minimum width that can be achieved by the light blocking patterns BMP including organic matter. Therefore, the display device 10 according to the current embodiment uses the touch electrodes including metal as members for controlling the viewing angle. This may be advantageous for controlling the viewing angle of the high-resolution display device 10 compared with when a plurality of light blocking layers LS including organic matter are stacked in multiple layers in the light control layer LCL. In addition, since the touch electrodes of the touch sensor layer TSU are used to control the viewing angle, a process for stacking the light blocking layer LS in multiple layers in the light control layer LCL is unnecessary. Therefore, the process efficiency can be effectively improved.

Hereinafter, other embodiments of the display device 10 according to the embodiment will be described. In the following embodiments, the same elements as those of the above-described embodiment will be indicated by the same reference numerals, and their redundant description will be omitted or given briefly, and differences will be mainly described.

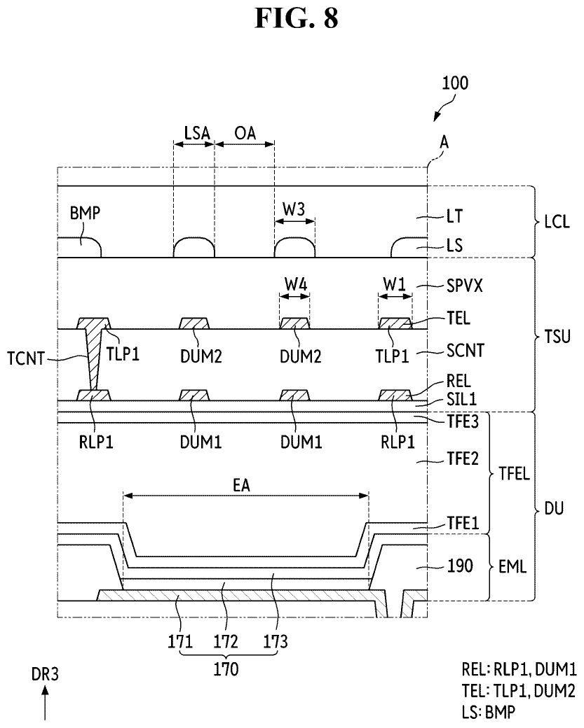

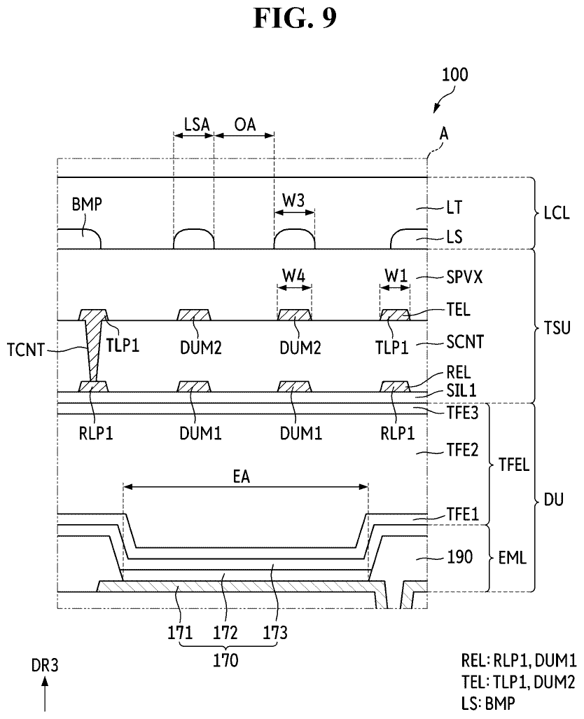

FIG. 8 is an enlarged view of area A of FIG. 6 in a display device 10 according to another embodiment. FIG. 9 is an enlarged view of area A of FIG. 6 in a display device 10 according to still another embodiment.

Referring to FIGS. 8 and 9 in addition to FIGS. 5 through 7, the display devices 10 according to the current embodiments are different from the display device 10 according to the embodiment described with reference to FIG. 7, etc. in that a plurality of first pattern electrodes RLP1 and DUM1 include first dummy electrodes DUM1 instead of the second sub-pattern electrodes RLP2, and a plurality of second pattern electrodes TLP1 and DUM2 include second dummy electrodes DUM2 instead of the fourth sub-pattern electrodes TLP2.

More specifically, a first touch conductive layer REL may include a plurality of first pattern electrodes RLP1 and DUM1. The first pattern electrodes RLP1 and DUM1 may be spaced apart from each other. The first pattern electrodes RLP1 and DUM1 may include first sub-pattern electrodes RLP1 and the first dummy electrodes DUM1. The first dummy electrodes DUM1 may be disposed between the first sub-pattern electrodes RLP1. For example, as illustrated in the drawings, two first dummy electrodes DUM1 may be disposed between two first sub-pattern electrodes RLP1. However, the present disclosure is not limited thereto, and one first dummy electrode DUM1 or three or more first dummy electrodes DUM1 may also be disposed between two first sub-pattern electrodes RLP1 in another embodiment.

A second touch conductive layer TEL may include a plurality of second pattern electrodes TLP1 and DUM2. The second pattern electrodes TLP1 and DUM2 may be spaced apart from each other. The second pattern electrodes TLP1 and DUM2 may include third sub-pattern electrodes TLP1 and the second dummy electrodes DUM2. The second dummy electrodes DUM2 may be disposed between the third sub-pattern electrodes TLP1. For example, as illustrated in the drawings, two second dummy electrodes DUM2 may be disposed between two third sub-pattern electrodes TLP1. However, the present disclosure is not limited thereto, and one second dummy electrode DUM2 or three or more second dummy electrodes DUM2 may be disposed between two third sub-pattern electrodes TLP1.

A plurality of light blocking patterns BMP may overlap the first sub-pattern electrodes RLP1, the first dummy electrodes DUM1, the third sub-pattern electrodes TLP1, and the second dummy electrodes DUM2 in the third direction DR3, respectively in a plan view. The first dummy electrodes DUM1 and the second dummy electrode DUM2 may overlap an emission area EA in the third direction DR3.

In the display devices 10 according to the current embodiments, the first pattern electrodes RLP1 and DUM1 of the first touch conductive layer REL, the second pattern electrodes TLP1 and DUM2 of the second touch conductive layer TEL, and the light blocking patterns BMP of a light blocking layer LS may block light emitted from a light emitting layer 172. Accordingly, light traveling at a predetermined angle or less with respect to the third direction DR3 may be output to the outside without being blocked by the first pattern electrodes RLP1 and DUM1 of the first touch conductive layer REL, the second pattern electrodes TLP1 and DUM2 of the second touch conductive layer TEL, and the light blocking patterns BMP of the light blocking layer LS, and light traveling at more than the predetermined angle with respect to the third direction DR3 may not be output to the outside by being blocked by the first pattern electrodes RLP1 and DUM1 of the first touch conductive layer REL, the second pattern electrodes TLP1 and DUM2 of the second touch conductive layer TEL, and the light blocking patterns BMP of the light blocking layer LS.

In the display devices 10 according to the current embodiments, the first sub-pattern electrodes RLP1 and the third sub-pattern electrodes TLP1 may be touch electrodes for sensing a user's touch. On the other hand, the first dummy electrodes DUM1 and the second dummy electrodes DUM2 may be dummy electrodes irrelevant to sensing of the user's touch. That is, the first dummy electrodes DUM1 and the second dummy electrodes DUM2 may only function as light blocking members and may not function as touch electrodes. In this case, while the first sub-pattern electrodes RLP1 and the third sub-pattern electrodes TLP1 can receive a driving signal from the touch driver circuit 400 (see FIG. 1) described above with reference to FIG. 1, etc. or provide a sensing signal to the touch driver circuit 400 (see FIG. 1), the first dummy electrodes DUM1 and the second dummy electrodes DUM2 may be electrically insulated from the first sub-pattern electrodes RLP1, the third sub-pattern electrodes TLP1, and the touch driver circuit 400.

When the first dummy electrodes DUM1 and the second dummy electrodes DUM2 do not function as touch electrodes, unlike the first sub-pattern electrodes RLP1 and the third sub-pattern electrodes TLP1, they are irrelevant to the uniformity and sensitivity of touch sensing. Therefore, each of widths of the first dummy electrodes DUM1 and the second dummy electrodes DUM2 may be different from each of widths of the first sub-pattern electrodes RLP1 and the third sub-pattern electrodes TLP1. For example, a width W1 of each third sub-pattern electrode TLP1 may be different from a width W4 of each second dummy electrode DUM2. Although not illustrated in the drawings, a width of each first sub-pattern electrode RLP1 may be different from a width of each first dummy electrode DUM1 for the same reason.

For example, as illustrated in FIG. 8, the width W1 of each third sub-pattern electrode TLP1 may be greater than the width W4 of each second dummy electrode DUM2, and the width of each first sub-pattern electrode RLP1 may be greater than the width of each first dummy electrode DUM1. For another example, as illustrated in FIG. 9, the width W1 of each third sub-pattern electrode TLP1 may be smaller than the width W4 of each second dummy electrode DUM2, and the width of each first sub-pattern electrode RLP1 may be smaller than the width of each first dummy electrode DUM1.

In some embodiments, the width of each of the first sub-pattern electrodes RLP1, the third sub-pattern electrodes TLP1, the first dummy electrodes DUM1, and the second dummy electrodes DUM2 may be different from a width W3 of each light blocking pattern BMP. For example, the width W1 of each third sub-pattern electrode TLP1 and the width W4 of each second dummy electrode DUM2 may be smaller than the width W3 of each light blocking pattern BMP. Likewise, although not illustrated in the drawings, the width of each first sub-pattern electrode RLP1 and the width of each first dummy electrode DUM1 may be smaller than the width W3 of each light blocking pattern BMP.

In the following embodiments, a case where a display device 10 includes the first through fourth sub-pattern electrodes RLP1, RLP2, TLP1 and TLP2 will be described as an example. However, the same technical spirit may also be applied to a case where a display device 10 includes the first sub-pattern electrodes RLP1, the third sub-pattern electrodes RLP3, the first dummy electrodes DUM1 and the second dummy electrodes DUM2, like the display devices 10 according to the embodiments described with reference to FIGS. 8 and 9.

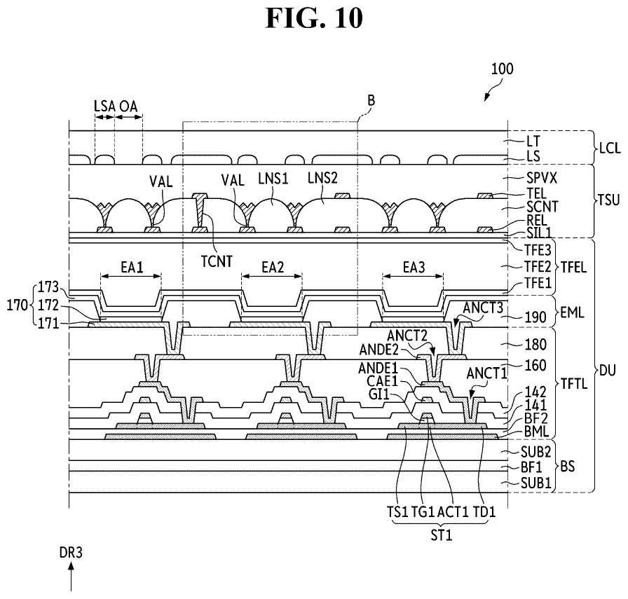

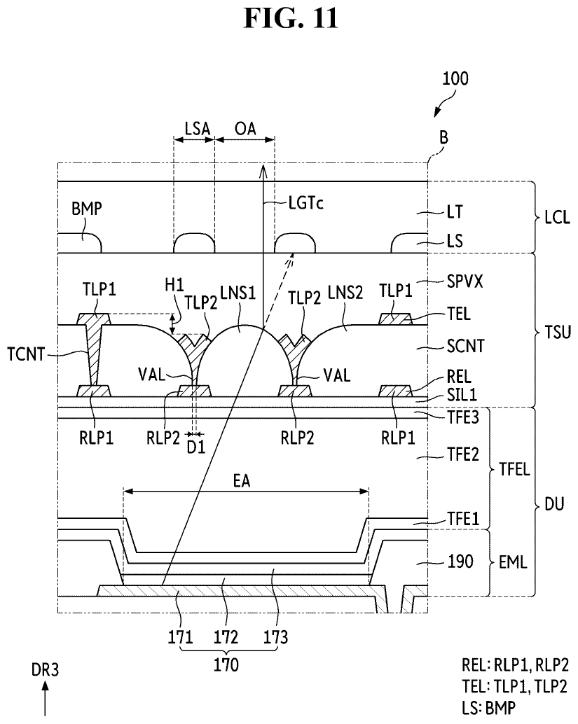

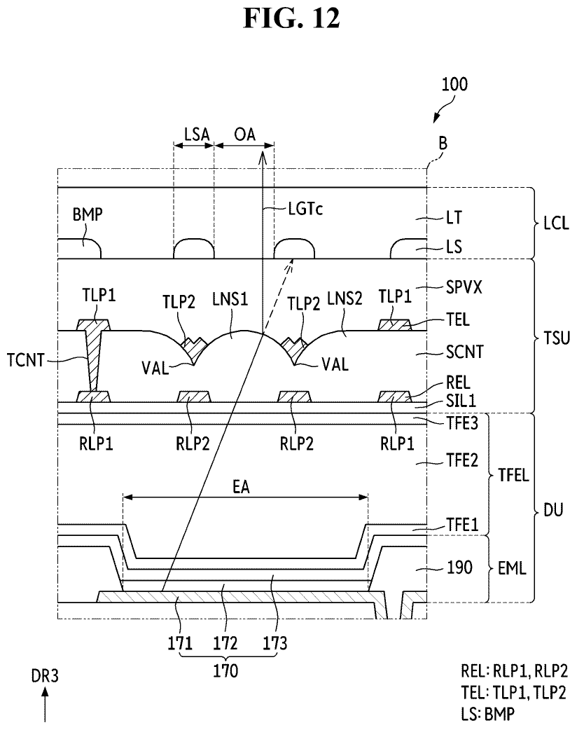

FIG. 10 is a cross-sectional view of a display device 10 according to another embodiment. FIG. 11 is an enlarged view of area B of FIG. 10. FIG. 12 is an enlarged view of area B of FIG. 10 in a display device 10 according to another embodiment.

Referring to FIGS. 10 through 12, the display devices 10 according to the current embodiments are different from the display devices 10 according to the embodiments described with reference to FIGS. 6 through 9 in that a touch sensor layer TSU includes lens portions LNS1 and LNS2.

More specifically, a second touch insulating layer SCNT of the touch sensor layer TSU may include the lens portions LNS1 and LNS2. The lens portions LNS1 and LNS2 may include first lens portions LNS1 and second lens portions LNS2. The first lens portions LNS1 and the second lens portions LNS2 may be disposed alternately in a direction perpendicular to the third direction DR3 (e.g., the first direction DR1 or the second direction DR2). In an embodiment, as illustrated in FIG. 11, the first lens portions LNS1 and the second lens portions LNS2 may be spaced apart by a first distance D1. In an embodiment, as illustrated in FIG. 12, the first lens portions LNS1 and the second lens portions LNS2 may directly contact each other or may be physically coupled to each other to form a single body.

The first lens portions LNS1 may at least partially overlap second sub-pattern electrodes RLP2 and fourth sub-pattern electrodes TLP2 in the third direction DR3. For example, opposite ends of each first lens portion LNS1 may overlap about halves of the second sub-pattern electrodes RLP2 and about halves of the fourth sub-pattern electrodes TLP2, respectively in a plan view.

The second lens portions LNS2 may at least partially overlap the first through fourth sub-pattern electrodes RLP1, RLP2, TLP1 and TLP2 in a plan view. For example, each second lens portion LNS2 may overlap the entire first sub-pattern electrode RLP1 and the entire third sub-pattern electrode TLP1 in about a center thereof, and opposite ends of each second lens portion LNS2 may overlap about halves of the second sub-pattern electrodes RLP2 and about halves of the fourth sub-pattern electrodes TLP2, respectively in a plan view.

In some embodiments, when the first lens portions LNS1 and the second lens portions LNS2 are spaced apart from each other by the first distance D1 as illustrated in FIG. 11, the second sub-pattern electrodes RLP2 and the fourth sub-pattern electrodes TLP2 may directly contact each other. In an embodiment, when the first lens portions LNS1 and the second lens portions LNS2 directly contact each other or are physically coupled to each other to form a single body as illustrated in FIG. 12, the second sub-pattern electrodes RLP2 and the fourth sub-pattern electrodes TLP2 may be spaced apart from each other.

The first lens portions LNS1 may be convex toward a light control layer LCL. Each of the second lens portions LNS2 may be convex on both sides toward the light control layer LCL and may be flat in about the center.

Valleys VAL may be located between the first lens portions LNS1 and the second lens portions LNS2 (in the case of FIG. 11) or at junctions between the first lens portions LNS1 and the second lens portions LNS2 (in the case of FIG. 12). The valleys VAL may be located on the second sub-pattern electrodes RLP2. The fourth sub-pattern electrodes TLP2 may be disposed within the valleys VAL. In some embodiments, the fourth sub-pattern electrodes TLP2 may be located at a height lower than the third sub-pattern electrodes TLP1 by a first height H1.

The lens portions LNS1 and LNS2 may collect light emitted from light emitting layers 172 to improve the light output efficiency in a forward direction. For example, as illustrated in FIGS. 11 and 12, third light LGTc traveling obliquely with respect to the third direction DR3 may be collected on convex surfaces of the lens portions LNS1 and LNS2 and then output in the forward direction. In this way, the amount of light output in the forward direction in the third direction DR3 may be increased, and the amount of light output in a side direction may be reduced, thereby improving the viewing angle control characteristics of the display devices 10.

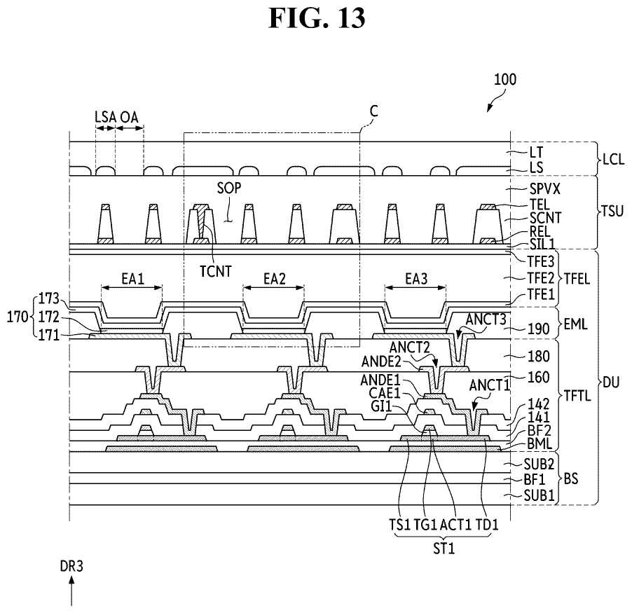

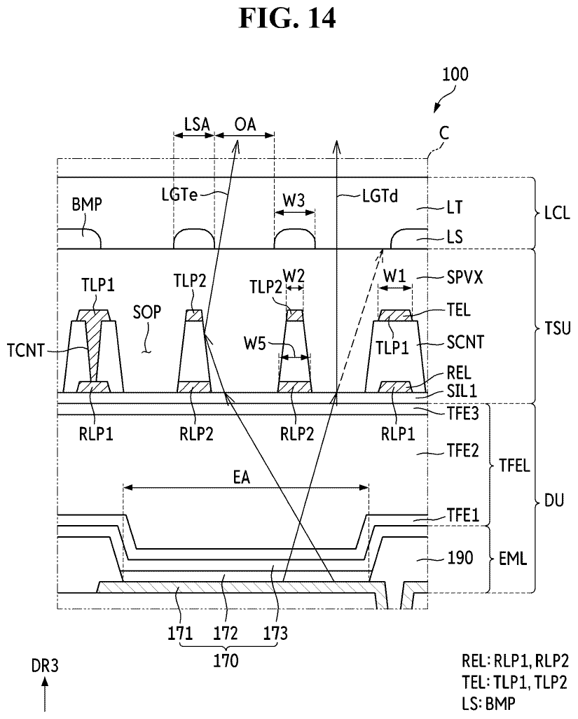

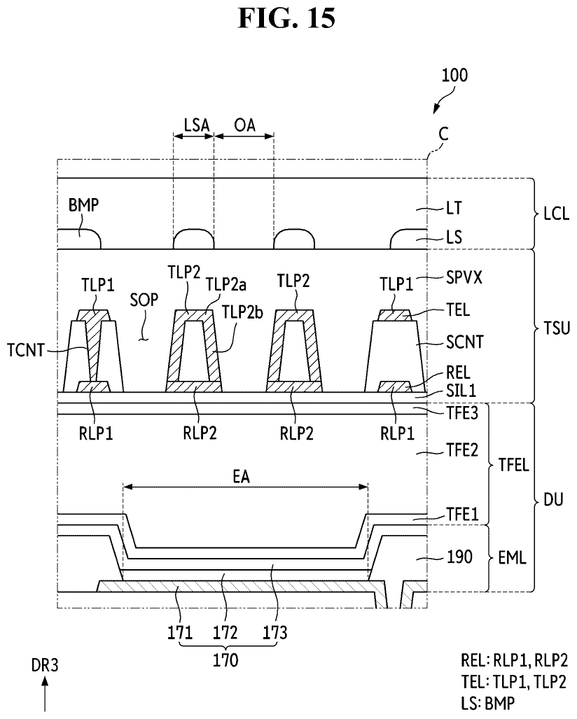

FIG. 13 is a cross-sectional view of a display device 10 according to still another embodiment. FIG. 14 is an enlarged view of area C of FIG. 13. FIG. 15 is an enlarged view of area C of FIG. 13 in a display device 10 according to another embodiment.

Referring to FIGS. 13 through 15, the display devices 10 according to the current embodiments are different from the display devices 10 according to the embodiments described above with reference to FIGS. 6 through 12 in that a second touch insulating layer SCNT defines openings SOP therein.

More specifically, the second touch insulating layer SCNT of a touch sensor layer TSU may define the openings SOP therein. The openings SOP of the second touch insulating layer SCNT may be provided between a plurality of first pattern electrodes RLP1 and RLP2. For example, the openings SOP of the second touch insulating layer SCNT may be provided between first sub-pattern electrodes RLP1 and second sub-pattern electrodes RLP2 and between the second sub-pattern electrodes RLP2.

In an embodiment, the openings SOP of the second touch insulating layer SCNT may not overlap the first pattern electrodes RLP1 and RLP2 and a plurality of second pattern electrodes TLP1 and TLP2 in a plan view, but the present disclosure is not limited thereto.

The first sub-pattern electrodes RLP1 may be covered by the second touch insulating layer SCNT in areas other than the openings SOP of the second touch insulating layer SCNT. The second sub-pattern electrodes RLP2 may be disposed under the second touch insulating layer SCNT in areas other than the openings SOP of the second touch insulating layer SCNT. Third sub-pattern electrodes TLP1 may be disposed on the second touch insulating layer SCNT in areas other than the openings SOP of the second touch insulating layer SCNT.

In an embodiment, as illustrated in FIG. 14, fourth sub-pattern electrodes TLP2 may be disposed on the second touch insulating layer SCNT in areas other than the openings SOP of the second touch insulating layer SCNT. In some embodiments, as illustrated in FIG. 14, a width W1 of each third sub-pattern electrode TLP1 may be greater than a width W2 of each fourth sub-pattern electrode TLP2. A width W5 of each second sub-pattern electrode RLP2 may be greater than the width W2 of each fourth sub-pattern electrode TLP2.

In an embodiment, as illustrated in FIG. 15, the fourth sub-pattern electrodes TLP2 may be disposed not only on an upper surface of the second touch insulating layer SCNT but also on inner side surfaces of the openings SOP of the second touch insulating layer SCNT. For example, each of the fourth sub-pattern electrodes TLP2 may include a first portion TLP2a disposed on the upper surface of the second touch insulating layer SCNT and a second portion TLP2b disposed on the inner side surfaces of the openings SOP of the second touch insulating layer SCNT. The first portion TLP2a and the second portion TLP2b may be physically coupled to each other to form a single body.

In some embodiments, as illustrated in FIG. 15, the second portions TLP2b of the fourth sub-pattern electrodes TLP2 may directly contact the second sub-pattern electrodes RLP2. In this case, a touch contact hole TCNT connecting a first sub-pattern electrode RLP1 and a third sub-pattern electrode TLP1 may be omitted.

A third touch insulating layer SPVX may be disposed in the openings SOP of the second touch insulating layer SCNT. The third touch insulating layer SPVX may not only be disposed on the second touch insulating layer SCNT but also fill the openings SOP of the second touch insulating layer SCNT.

In some embodiments, a refractive index of the third touch insulating layer SPVX may be greater than a refractive index of a second encapsulation layer TFE2. For example, a difference between the refractive index of the third touch insulating layer SPVX and the refractive index of the second encapsulation layer TFE2 may be about 0.1 or greater. In an embodiment, the refractive index of the third touch insulating layer SPVX may be about 1.5 to 1.7, and the refractive index of the second encapsulation layer TFE2 may be about 1.4 to 1.6.

In the present specification, a refractive index refers to an absolute refractive index measured using a D line (a wavelength λ of about 589 nm: yellow) of natrium (or sodium) at room temperature and humidity (a temperature of 20±15° C. and a humidity of 65±20%). For example, in the present specification, the refractive index may be an absolute refractive index measured based on a wavelength of 589 nm according to a Cauchy film model by using a refractive index measuring device (e.g., Ellipsometer (Ellipsometer M-2000, J. A. Woollam)) at a temperature of 25° C. and a relative humidity of 65%.

Due to the difference in refractive index between the third touch insulating layer SPVX and the second sealing film TFE2, the light output efficiency in the forward direction can be effectively improved. For example, as illustrated in FIG. 14, fourth light LGTd traveling through the thin-film encapsulation layer TFEL and obliquely with respect to the third direction DR3 may be refracted by a lower surface of the third touch insulating layer SPVX to travel in the forward direction (e.g., third direction DR3). In this way, the amount of light output in the forward direction in the third direction DR3 may be increased, and the amount of light output in the side direction may be reduced, thereby improving the viewing angle control characteristics of the display devices 10.

In some embodiments, the refractive index of the third touch insulating layer SPVX may be greater than a refractive index of the second touch insulating layer SCNT. For example, a difference between the refractive index of the third touch insulating layer SPVX and the refractive index of the second touch insulating layer SCNT may be about 0.1 or more. In an embodiment, the refractive index of the second touch insulating layer SCNT may be about 1.4 to 1.6.

Due to the difference in refractive index between the third touch insulating layer SPVX and the second touch insulating layer SCNT, the light output efficiency in the forward direction can be effectively improved. For example, as illustrated in FIG. 14, fifth light LGTe traveling through the thin-film encapsulation layer TFEL and obliquely with respect to the third direction DR3 may be totally reflected at an interface between the second touch insulating layer SCNT and the third touch insulating layer SPVX to travel in the forward direction. In this way, the amount of light output in the forward direction in the third direction DR3 may be increased, and the amount of light output in the side direction may be reduced, thereby improving the viewing angle control characteristics of the display devices 10.

Even in the case of the display device 10 according to the embodiment described above with reference to FIGS. 6 and 7, if a refractive index of the second touch insulating layer SCNT is greater than a refractive index of the second encapsulation layer TFE2, the viewing angle control characteristics of the display device 10 can be effectively improved to the same effect. For example, in some embodiments, a difference between the refractive index of the second touch insulating layer SCNT and the refractive index of the second encapsulation layer TFE2 of the display device 10 according to the embodiment described with reference to FIGS. 6 and 7 may be 0.1 or more. In this case, the refractive index of the second touch insulating layer SCNT may be about 1.5 to 1.7, and the refractive index of the second encapsulation layer TFE2 may be about 1.4 to 1.6.

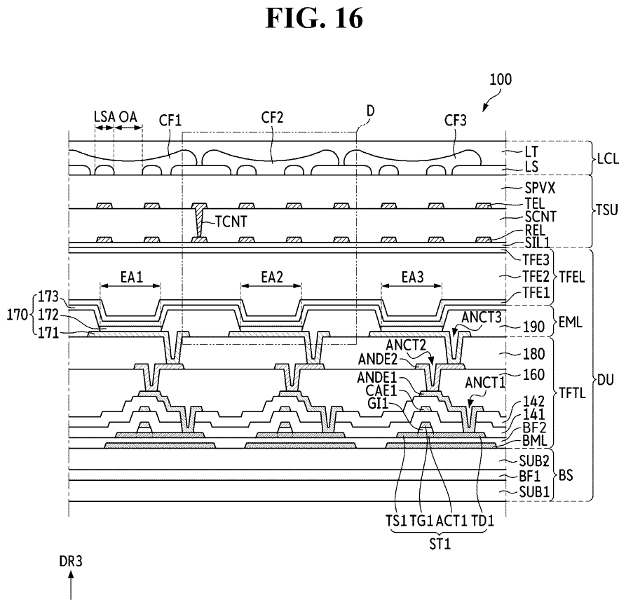

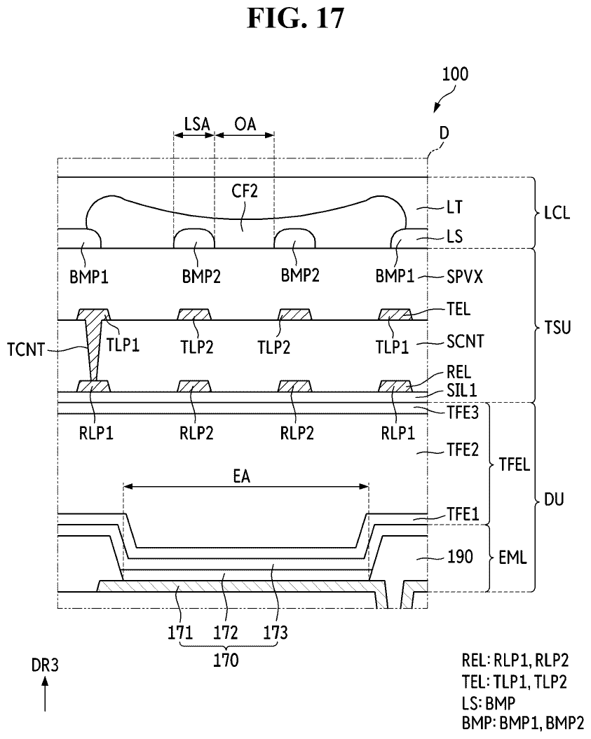

FIG. 16 is a cross-sectional view of a display device 10 according to yet another embodiment. FIG. 17 is an enlarged view of area D of FIG. 16.

Referring to FIGS. 16 and 17, the display device 10 according to the current embodiment is different from the display devices 10 according to the embodiments described with reference to FIGS. 6 through 15 in that a light control layer LCL includes color filters CF1 thorough CF3.

More specifically, in the display device 10 according to the current embodiment, the light control layer LCL may further include the color filters CF1 through CF3. The color filters CF1 through CF3 may be disposed on a light blocking layer LS. For example, the color filters CF1 through CF3 may be disposed between the light blocking layer LS and a light transmitting layer LT. The light transmitting layer LT may cover the color filters CF1 through CF3.

The color filters CF1 through CF3 may include a first color filter CF1 overlapping a first emission area EA1, a second color filter CF2 overlapping a second emission area EA2, and a third color filter CF3 overlapping a third emission area EA3 in a plan view.

Each of the color filters CF1 through CF3 may include a colorant such as a dye or pigment that absorbs light of wavelengths other than light of a specific wavelength and may be disposed to correspond to the color of light emitted by a light emitting element 170. For example, the first color filter CF1 may be a red color filter that transmits only red first light, the second color filter CF2 may be a green color filter that transmits only green second light, and the third color filter CF3 may be a blue color filter that transmits only blue third light.

The light blocking layer LS may include a plurality of light blocking patterns BMP. The light blocking patterns BMP may include first light blocking patterns BMP1 and second light blocking patterns BMP2. The first light blocking patterns BMP1 may overlap first sub-pattern electrodes RLP1 and third sub-pattern electrodes TLP1 in the third direction DR3. The second light blocking patterns BMP2 may overlap second sub-pattern electrodes RLP2 and fourth sub-pattern electrodes TLP2 in the third direction DR3.

The second light blocking patterns BMP2 may be disposed between the first light blocking patterns BMP1. For example, as illustrated in the drawings, two second light blocking patterns BMP2 may be disposed between two first light blocking patterns BMP1. However, the present disclosure is not limited thereto, and one second light blocking pattern BMP2 or three or more second light blocking patterns BMP2 may also be disposed between two first light blocking patterns BMP1 in another embodiment.

The color filters CF1 through CF3 may overlap the first light blocking patterns BMP1 and the second light blocking patterns BMP2 in a plan view. The color filters CF1 through CF3 may at least partially cover the first blocking patterns BMP1 and the second blocking patterns BMP2. For example, opposite ends of each of the color filters CF1 through CF3 may at least partially cover the first blocking patterns BMP1, and about a central portion of each of the color filters CF1 through CF3 may cover the whole of the second light blocking patterns BMP2.

The display device 10 according to the current embodiment can reduce the intensity of reflected light due to external light by including the color filters CF1 through CF3 disposed on a display layer DU. Furthermore, it can control the color of the reflected light due to the external light by adjusting the arrangement, shapes and areas of the color filters CF1 through CF3 in a plan view.

In concluding the detailed description, those skilled in the art will appreciate that many variations and modifications can be made to the preferred embodiments without substantially departing from the principles of the present disclosure. Therefore, the disclosed preferred embodiments of the invention are used in a generic and descriptive sense only and not for purposes of limitation.

What is claimed is:

1. A display device comprising:
a substrate;
a light emitting element layer disposed on the substrate and comprising a bank and a light emitting element overlapping an opening of the bank in a plan view;
a first touch conductive layer disposed on the light emitting element layer and comprising a first pattern electrode;
a first insulating layer disposed on the first touch conductive layer;
a second touch conductive layer disposed on the first insulating layer and comprising a second pattern electrode;
a second insulating layer disposed on the second touch conductive layer; and
a light blocking layer disposed on the second insulating layer and comprising a light blocking pattern,
wherein at least a portion of the first pattern electrode, at least a portion of the second pattern electrode, and at least a portion of the light blocking pattern overlap the light emitting element in the plan view.

2. The display device of claim 1, wherein
the first pattern electrode comprises a first sub-pattern electrode and a second sub-pattern electrode disposed between the first sub-pattern electrode and another first sub-pattern electrode,
the second pattern electrode comprises a third sub-pattern electrode and a fourth sub-pattern electrode disposed between the third sub-pattern electrode and another third sub-pattern electrode,
the first sub-pattern electrode, the another first sub-pattern electrode, the third sub-pattern electrode, and the another third sub-pattern electrode overlap the bank in the plan view, and
the second sub-pattern electrode and the fourth sub-pattern electrode overlap the light emitting element in the plan view.

3. The display device of claim 2, further comprising a touch driver electrically connected to the first touch conductive layer and the second touch conductive layer,
wherein the first through fourth sub-pattern electrodes are electrically connected to the touch driver.

4. The display device of claim 3, wherein widths of the first through fourth sub-pattern electrodes are equal to each other.

5. The display device of claim 2, wherein the first sub-pattern electrode and the third sub-pattern electrode are connected through a touch contact hole.

6. The display device of claim 2, further comprising a color filter disposed on the light blocking layer, wherein
the light blocking pattern comprises a first light blocking pattern overlapping the first sub-pattern electrode and a second light blocking pattern overlapping the second sub-pattern electrode in the plan view, and
the color filter covers a portion of the first light blocking pattern and covers an entirety of the second light blocking pattern.

7. The display device of claim 1, wherein a width of the light blocking pattern is different from each of a width of the first pattern electrode and a width of the second pattern electrode.

8. The display device of claim 1, further comprising an encapsulation layer disposed between the light emitting element layer and the first touch conductive layer,
wherein a refractive index of the first insulating layer is greater than a refractive index of the encapsulation layer.

9. The display device of claim 1, wherein
the first pattern electrode comprises a first sub-pattern electrode and a first dummy electrode disposed between the first sub-pattern electrode and another first sub-pattern electrode,
the second pattern electrode comprises a third sub-pattern electrode and a second dummy electrode disposed between the third sub-pattern electrode and another third sub-pattern electrode,
the first sub-pattern electrode, the another first sub-pattern electrode, the third sub-pattern electrode and the another third sub-pattern electrode overlap the bank in the plan view, and
the first dummy electrode and the second dummy electrode overlap the light emitting element in the plan view.

10. The display device of claim 9, further comprising a touch driver electrically connected to the first touch conductive layer and the second touch conductive layer, wherein
the first sub-pattern electrode and the third sub-pattern electrode are electrically connected to the touch driver, and
the first dummy electrode and the second dummy electrode are electrically insulated from the touch driver.

11. The display device of claim 10, wherein
a width of the first dummy electrode is different from a width of the first sub-pattern electrode, and
a width of the second dummy electrode is different from a width of the third sub-pattern electrode.

12. The display device of claim 1, wherein
the first insulating layer comprises a first lens portion and a second lens portion disposed alternately with the first lens portion, and
each of the first lens portion and the second lens portion comprises a surface convex toward the light blocking layer.

13. The display device of claim 12, wherein
a valley is disposed between the first lens portion and the second lens portion,
a portion of the first pattern electrode is disposed under the valley, and
a portion of the second pattern electrode is disposed in the valley.

14. The display device of claim 13, wherein
the first lens portion and the second lens portion are spaced apart from each other, and
the portion of the first pattern electrode disposed under the valley and the portion of the second pattern electrode disposed in the valley directly contact each other.

15. The display device of claim 13, wherein
the first lens portion and the second lens portion directly contact each other or are integrally formed with each other, and
the portion of the first pattern electrode disposed under the valley and the portion of the second pattern electrode disposed in the valley are spaced apart from each other.

16. The display device of claim 1, wherein the first pattern electrode is provided in plurality,
the first insulating layer defines an opening provided between the plurality of first pattern electrodes, and
the second insulating layer is further disposed in the opening of the first insulating layer.

17. The display device of claim 16, further comprising an encapsulation layer disposed between the light emitting element layer and the first touch conductive layer,
wherein a refractive index of the second insulating layer is greater than a refractive index of the encapsulation layer.

18. The display device of claim 16, wherein the at least a portion of the second pattern electrode overlapping the light emitting element comprises a first portion disposed on an upper surface of the first insulating layer and a second portion disposed on a side surface of the opening of the first insulating layer.

19. The display device of claim 18, wherein the second portion directly contacts the at least a portion of the first pattern electrode overlapping the light emitting element in the plan view.

20. An electronic device comprising a display device, the display device comprising:
a substrate;
a light emitting element layer disposed on the substrate and comprising a bank and a light emitting element overlapping an opening of the bank in a plan view;
a first touch conductive layer disposed on the light emitting element layer and comprising a first pattern electrode;
a first insulating layer disposed on the first touch conductive layer;
a second touch conductive layer disposed on the first insulating layer and comprising a second pattern electrode;
a second insulating layer disposed on the second touch conductive layer; and
a light blocking layer disposed on the second insulating layer and comprising a light blocking pattern,
wherein at least a portion of the first pattern electrode, at least a portion of the second pattern electrode, and at least a portion of the light blocking pattern overlap the light emitting element in the plan view.
